(19) United States
(12) Patent Application Publication
(10) Pub. No.: US 2025/0209765 A1
(43) Pub. Date: Jun. 26, 2025

(54) METHOD FOR DETERMINING MODEL ARRANGEMENT INFORMATION, ELECTRONIC DEVICE AND STORAGE MEDIUM

(71) Applicant: Hangzhou Qunhe Information Technology Co., Ltd, Hangzhou (CN)

(72) Inventors: Hao ZHU, Hangzhou (CN); Jiandong ZHOU, Hangzhou (CN); Taoyang XU, Hangzhou (CN); Yifan LIN, Hangzhou (CN); Biao ZHANG, Hangzhou (CN); Yujing YANG, Hangzhou (CN); Jing GUO, Hangzhou (CN)

(73) Assignee: Hangzhou Qunhe Information Technology Co., Ltd, Hangzhou (CN)

(21) Appl. No.: 19/001,248

(22) Filed: Dec. 24, 2024

(30) Foreign Application Priority Data
Dec. 25, 2023 (CN) 202311797717.9
Dec. 9, 2024 (CN) 202411803600.1

(51) Int. Cl. G06T 19/20; G06F 30/13

(52) U.S. Cl. CPC G06T 19/20; G06F 30/13; G06T 2200/24; G06T 2210/04; G06T 2219/2016; G06T 2219/2021

(57) ABSTRACT

Provided is a model arrangement information determination method, including: in response to triggering to arrange a first model on a house layout design drawing, displaying at least one capture element of the first model; in response to detecting a drag operation on a first capture element among the at least one capture element, moving the first capture element and the first model according to a trajectory corresponding to the drag operation and a relative position between the first capture element and the first model; and if a preset adsorption condition is met between the first reference line and the first capture element and an arrangement confirmation instruction input by a user is detected during movement, determining an arrangement position of the first capture element based on the first reference line, and determining an arrangement position of the first model based on the first capture element and the first model.

### CROSS-REFERENCE TO RELATED APPLICATIONS

The present application claims priorities to Chinese Patent Application No. CN202311797717.9, filed with the China National Intellectual Property Administration on Dec. 25, 2023, and Chinese Patent Application No. CN202411803600.1, filed with the China National Intellectual Property Administration on Dec. 9, 2024, the contents of which are hereby incorporated herein by reference in their entireties.

### TECHNICAL FIELD

The present disclosure relates to the field of computer technology, and in particular to a method for determining model arrangement information, an electronic device and a storage medium.

### BACKGROUND

With the development of the home decoration design industry, the number of users in the tool platform of home decoration design is becoming larger and larger. At the same time, the types of services that need to be covered are increasing, and the service scenarios are also becoming more and more complex. Therefore, the user requirements are also gradually becoming more refined. However, the existing tool platform of home decoration design cannot meet the users' requirements for accurate arrangement of models.

### SUMMARY

The present disclosure provides a method for determining model arrangement information, an electronic device and a storage medium, to solve or alleviate one or more technical problems in the related art.

In a first aspect, the present disclosure provides a method for determining model arrangement information, including:
in response to triggering to arrange a first model on a house layout design drawing, displaying at least one capture element of the first model; where the house layout design drawing includes a first reference line drawn according to a user operation instruction;
in response to detecting a drag operation on a first capture element among the at least one capture element, moving the first capture element and the first model according to a trajectory corresponding to the drag operation and a relative position between the first capture element and the first model; and
if a preset adsorption condition is met between the first reference line and the first capture element and an arrangement confirmation instruction input by a user is detected during movement, determining an arrangement position of the first capture element based on a position of the first reference line, and determining an arrangement position of the first model based on the relative position between the first capture element and the first model.

In one implementation, the method for determining the model arrangement information further includes:
in a reference line drawing mode, in response to detecting a datum point confirmation instruction on the house layout design drawing, determining reference line datum information based on a detection position of the datum point confirmation instruction, and starting to detect a drawing confirmation instruction on the house layout design drawing; and
generating the first reference line on the house layout design drawing based on the reference line datum information and position information indicated by the drawing confirmation instruction.

In one implementation, when a datum point indicated by the datum point confirmation instruction is located on a linear element in the house layout design drawing, the reference line datum information is the linear element; and
generating the first reference line on the house layout design drawing based on the reference line datum information and the position information indicated by the drawing confirmation instruction, includes:
generating the first reference line parallel to the linear element on the house layout design drawing according to a distance value included in the drawing confirmation instruction and/or a detection position of the drawing confirmation instruction.

In one implementation, the linear element in the house layout design drawing includes at least one of: a second reference line drawn according to a user operation instruction, a line segment of a house layout component, or an external frame line of a second model arranged on the house layout design drawing.

In one implementation, when a datum point indicated by the datum point confirmation instruction is not located on a linear element in the house layout design drawing, the reference line datum information is the datum point; and the first reference line penetrates through the datum point and the position information indicated by the drawing confirmation instruction.

In one implementation, the at least one capture element includes at least one of: an element on an external frame of the first model, a point on a mesh surface of the first model, a key point determined when the first model is modeled, an auxiliary line segment of the first model, or a key point on the auxiliary line segment.

In one implementation, the method for determining the model arrangement information further includes:
in an auxiliary line drawing mode, detecting a start point confirmation instruction and an end point confirmation instruction detected on the house layout design drawing;
generating the auxiliary line segment based on a start point indicated by the start point confirmation instruction and an end point indicated by the end point confirmation instruction; and
binding the auxiliary line segment with the first model.

In one implementation, the start point confirmation instruction includes a click instruction for the start point, or a confirmation instruction for adsorbing a point on the house layout design drawing as the start point; and
the end point confirmation instruction includes a click instruction for the end point, or a confirmation instruction for adsorbing a point on the house layout design drawing as the end point.

In one implementation, the in response to triggering to arrange a first model on a house layout design drawing, displaying at least one capture element of the first model, includes:
in response to triggering to arrange a first model on a house layout design drawing, determining a type of a capture element to be displayed according to size information of an external frame of the first model; and
displaying at least one capture element of the first model according to the type of the capture element to be displayed.

In one implementation, when the size information of the external frame of the first model is greater than a preset first threshold, the type of the capture element to be displayed includes at least one of: an element on the external frame of the first model, a point on a mesh surface of the first model, a key point determined when the first model is modeled, an auxiliary line segment of the first model, or a key point on the auxiliary line segment.

In one implementation, when the size information of the external frame of the first model is less than the preset first threshold, the type of the capture element to be displayed includes at least one of: an element on the external frame of the first model, and an auxiliary line segment of the first model.

In one implementation, in an arrangement off mode, the at least one capture element includes an element on an external frame of the first model.

In one implementation, in an arrangement on mode, the at least one capture element includes at least one of: an element on an external frame of the first model, a point on a mesh surface of the first model, a key point determined when the first model is modeled, an auxiliary line segment of the first model, or a key point on the auxiliary line segment.

In a second aspect, the present disclosure provides a method for controlling model operation, including:
in response to detecting that a capture condition is met between a cursor position in a model arrangement space and any capture element of the first model, displaying type information of the capture element;
in response to detecting a confirmation operation for the type information, determining processing information related to the capture element based on movement of the cursor position; and
determining arrangement information of the first model based on the processing information related to the capture element and a relative position between the capture element and the first model.

In one implementation, the processing information related to the capture element includes: a movement position of the capture element in a movement mode; and
determining the arrangement information of the first model based on the processing information related to the capture element and the relative position between the capture element and the first model, includes:
determining a movement position of the first model based on the movement position of the capture element and the relative position between the capture element and the first model.

In one implementation, the processing information related to the capture element includes: a movement position of the capture element in a copy mode;
determining the arrangement information of the first model based on the processing information related to the capture element and the relative position between the capture element and the first model, includes:
in response to detecting a confirmation operation for the movement position of the capture element, determining the movement position of the capture element as a copy end point; and
determining a copy position of the first model based on the copy end point and the relative position between the capture element and the first model;
the method for controlling model operation further includes:
displaying a copied object of the first model at the copy position.

In one implementation, the processing information related to the capture element includes: a movement position of the capture element in a scaling mode;
determining the arrangement information of the first model based on the processing information related to the capture element and the relative position between the capture element and the first model, includes:
determining a scaling parameter of the first model based on the movement position of the capture element and the relative position between the capture element and the first model;
the method for controlling model operation further includes:
displaying the scaled first model based on a scaling type corresponding to the type information of the capture element and the scaling parameter.

In one implementation, the method for controlling model operation further includes:
in the scaling mode, in response to detecting in the model arrangement space that the capture condition is met between the cursor position and any capture element of the first model, displaying a scaling handle based on the type information of the capture element; where the scaling handle is used to prompt the scaling type corresponding to the type information of the capture element.

In one implementation, the processing information related to the capture element includes: an angle of rotation with the capture element as a rotation center point in a rotation mode; and
determining the arrangement information of the first model based on the processing information related to the capture element and the relative position between the capture element and the first model, includes:
determining a rotation plane based on the type information of the capture element; and
rotating the first model with a normal of the rotation plane as a rotation axis based on the relative position between the capture element and the first model and the angle, to obtain a rotation position of the first model.

In one implementation, determining the processing information related to the capture element based on the movement of the cursor position, includes:
in response to detecting a first confirmation operation during movement of the cursor position, determining a rotation start edge; where the rotation start edge penetrates through the capture element and a detection point corresponding to the first confirmation operation;
in response to detecting a second confirmation operation during movement of the cursor position, determining a rotation end edge; where the rotation end edge penetrates through the capture element and a detection point corresponding to the second confirmation operation; and
determining the angle of rotation with the capture element as the rotation center point based on the rotation start edge and the rotation end edge.

In one implementation, the method for controlling model operation further includes:
in the rotation mode, in response to detecting in the model arrangement space that an adsorption condition is met between the cursor position and any capture element of the first model and the type information of the capture element is a vertex of a bounding box of the first model, displaying a rotation plane identifier on a plane intersecting with the cursor position on the bounding box, and detecting a confirmation operation for the type information; where the confirmation operation for the type information is further used to confirm the plane intersecting with the cursor position as the rotation plane.

In one implementation, when the type information of the capture element is not a pre- set specific type, the rotation plane is a default plane; and the specific type includes a vertex of a bounding box of the first model, a center point of each plane on the bounding box, and an edge of the bounding box.

In one implementation, determining the processing information related to the capture element based on the movement of the cursor position, includes:
when the cursor position moves to meet the adsorption condition with respect to a reference element in the model arrangement space, determining the processing information related to the capture element based on a position of the reference element.

In one implementation, the reference element includes a straight line along an axial direction of the model arrangement space.

In one implementation, the method for controlling model operation further includes:
when the cursor position and a capture element invisible from a current viewing angle of a camera meet the capture condition, reducing display transparency of the first model to display the capture element.

In a third aspect, provided is an electronic device, including:
at least one processor; and
a memory connected in communication with the at least one processor;
where the memory stores an instruction executable by the at least one processor, and the instruction, when executed by the at least one processor, enables the at least one processor to execute the method of any embodiment of the present disclosure.

In a fourth aspect, provided is a non-transitory computer-readable storage medium storing a computer instruction thereon, and the computer instruction is used to cause a computer to execute the method of any embodiment of the present disclosure.

The beneficial effects of the technical solution provided in the present disclosure at least include: the reference line drawn according to the user operation instruction can be displayed on the house layout design drawing, and the user can move the capture element and correspondingly move the first model through the drag operation on the capture element of the first model. The user only needs to move the capture element to a position at which the adsorption condition is met with respect to the reference line according to requirements, so that the arrangement position of the first capture element can be accurately determined based on the position of the reference line, and the arrangement position of the first model can be determined based on the relative position between the capture element and the first model. Therefore, the model can be moved and placed accurately, and the efficiency of model arrangement can be improved, so that the solution of the present disclosure can be applied to the actual model arrangement link to realize accurate model arrangement in various scenarios.

It should be understood that the content described in this part is not intended to identify critical or essential features of embodiments of the present disclosure, nor is it used to limit the scope of the present disclosure. Other features of the present disclosure will be easily understood through the following description.

### BRIEF DESCRIPTION OF THE DRAWINGS

In the accompanying drawings, the same reference numbers represent the same or similar parts or elements throughout the accompanying drawings, unless otherwise specified. These accompanying drawings are not necessarily drawn to scale. It should be understood that these accompanying drawings only depict some embodiments provided according to the present disclosure, and should not be considered as limiting the scope of the present disclosure.

FIG. 1 is a schematic diagram of a method for controlling model operation according to an embodiment of the present disclosure;

FIG. 2 is a schematic flow chart of a method for determining model arrangement information according to an embodiment of the present disclosure;

FIG. 3 is a schematic diagram of an interface for moving the model to the arrangement position according to an embodiment of the present disclosure;

FIG. 4 is a schematic diagram of an entry of the drawing mode according to an embodiment of the present disclosure;

FIG. 5A is a first schematic diagram of an interface of the drawing mode of the reference line in an embodiment of the present disclosure;

FIG. 5B is a second schematic diagram of an interface of the drawing mode of the reference line in an embodiment of the present disclosure;

FIG. 6 is a schematic diagram of an interface of the drawing mode of the auxiliary line segment in an embodiment of the present disclosure;

FIG. 7 is a schematic diagram of a method for controlling model operation according to another embodiment of the present disclosure;

FIG. 8A is a first schematic diagram showing the type information of the capture element;

FIG. 8B is a second schematic diagram showing the type information of the capture element;

FIG. 8C is a third schematic diagram showing the type information of the capture element;

FIG. 9A is a schematic diagram of coaxial scaling;

FIG. 9B is a schematic diagram of non-proportional scaling;

FIG. 9C is a schematic diagram of proportional scaling;

FIG. 10 is a schematic diagram of the operation manner in the scaling mode;

FIG. 11A is a first schematic diagram of the operation manner in the rotation mode;

FIG. 11B is a second schematic diagram of the operation manner in the rotation mode;

FIG. 11C is a third schematic diagram of the operation manner in the rotation mode;

FIG. 12 is a schematic diagram of the plane intersecting with the cursor position on the bounding box;

FIG. 13 is a schematic block diagram of an apparatus for determining model arrangement information according to an embodiment of the present disclosure;

FIG. 14 is a schematic block diagram of an apparatus for determining model arrangement information according to another embodiment of the present disclosure;

FIG. 15 is a schematic block diagram of an apparatus for controlling model operation according to an embodiment of the present disclosure;

FIG. 16 is a schematic block diagram of an apparatus for controlling model operation according to another embodiment of the present disclosure; and

FIG. 17 is a block diagram of an electronic device for implementing the method of the embodiment of the present disclosure.

### DETAILED DESCRIPTION

The present disclosure will be described below in detail with reference to the accompanying drawings. The same reference numbers in the accompanying drawings represent elements with identical or similar functions. Although various aspects of the embodiments are shown in the accompanying drawings, the accompanying drawings are not necessarily drawn to scale unless specifically indicated.

In addition, in order to better illustrate the present disclosure, numerous specific details are given in the following specific implementations. Those having ordinary skill in the art should understand that the present disclosure may be performed without certain specific details. In some examples, methods, means, elements and circuits well known to those having ordinary skill in the art are not described in detail, in order to highlight the subject matter of the present disclosure.

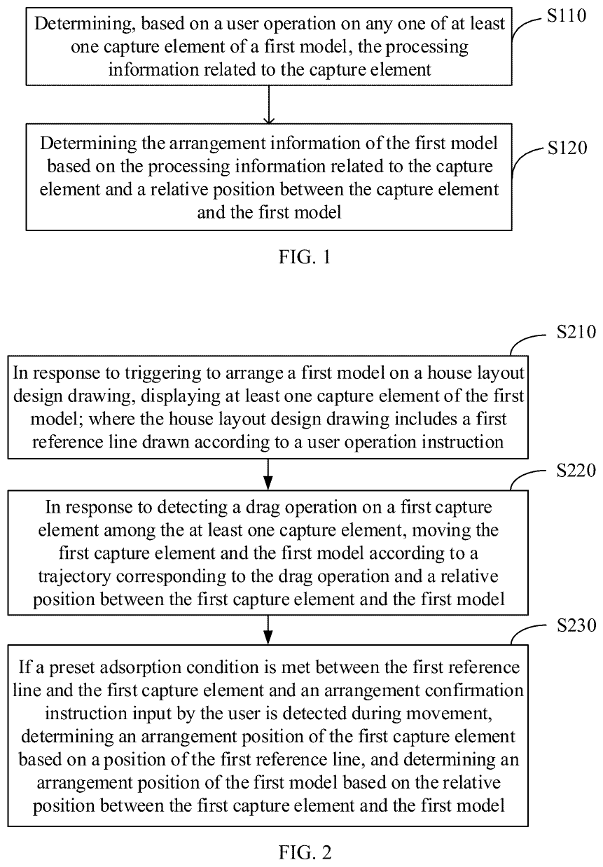

FIG. 1 shows a schematic diagram of a method for controlling model operation according to an embodiment of the present disclosure. This method may be applied to an electronic device. As shown in FIG. 1, this method may include:
S110: determining, based on a user operation on any one of at least one capture element of a first model, the processing information related to the capture element.
S120: determining the arrangement information of the first model based on the processing information related to the capture element and a relative position between the capture element and the first model.

The embodiment of the present disclosure may be applied to a tool platform for home decoration design, a user may operate on a visual interactive interface through an electronic device, and the electronic device may move and place the model in response to the user operation. Here, the interactive interface may be an interactive interface displayed by a display unit of the electronic device, or an interactive interface displayed by a display unit of another electronic device connected to the electronic device. Specifically, the interactive interface may display a model arrangement space (for example, a house layout design drawing), and the user may arrange the first model at any position in the model arrangement space by operating on the interactive interface.

Optionally, the model arrangement space may be a space displayed on the interactive interface. Exemplarily, the model arrangement space may be presented in the form of a house layout design drawing. Optionally, the model arrangement space may be a 2D (2 Dimensions) space or 3D (3 Dimensions) space. Accordingly, the house layout design drawing may be a 2D design drawing or 3D design drawing. Here, the 2D design drawing may be a top view image or a facade image of the house layout space.

Optionally, the first model is an object model to be operated. Exemplarily, the model arrangement space may include a plurality of models, including the first model; and the user may directly select the first model in the model arrangement space, and for example, move the cursor into the display area of the first model. When the model arrangement space does not include the first model, the electronic device may use a model read from a designated path as the first model and display the first model in the house layout design drawing. For example, the user may select the first model from the pre-configured model styles displayed, or draw the first model in a third-party software (such as CAD) and store it in the designated path. The user may input the path related to the first model, and the electronic device may read the first model according to the input path.

Optionally, the capture element of the first model may be any point or line segment related to the first model in the model arrangement space, and the position of the capture element may be on the first model or may not be on the first model. The types, positions and number of capture elements may vary from model to model. Optionally, one part of the capture elements may be some key points, line segments and other elements on the first model, and the other part of the capture elements may be points, line segments and other elements pre-bound with the first model. These capture elements may be on the first model or may not be on the first model. There is a relative position between the capture element and the first model. For example, the capture element may be a center point of the first model, and then the capture element is always located at the position of the center point of the first model. The capture element and the first model may move synchronously, and the electronic device may obtain the relative position relationship between the capture element and the first model, and determine the position of the first model according to the position of the capture element. Optionally, there may be a plurality of capture elements.

In actual applications, the capture elements of the first model may be firstly displayed on the interactive interface, so that the user can perform user operations on the capture elements.

When the electronic device detects a user operation, the electronic device determines the processing information related to the capture element based on the user operation. For example, the user operation may include one or more operations such as a confirmation operation (such as clicking, selecting, etc.) and a drag operation (such as controlling the cursor to move) related to the capture element. The electronic device may determine the related processing information such as movement position (or arrangement position) and movement trajectory of the capture element based on these user operations. There is a relative position between the capture element and the first model. After the processing information related to the capture element is obtained, the first model may be processed accordingly based on the relative position. For example, the position and movement trajectory of the first model are determined based on the position and movement trajectory of the capture element. It can be seen that the user can control/arrange the first model in the model arrangement space based on the capture element according to the embodiment of the present disclosure.

FIG. 2 shows a schematic diagram of a method for determining model arrangement information according to an embodiment of the present disclosure. This method may be applied to an apparatus for determining model arrangement information, and this apparatus may be deployed in an electronic device. The electronic device is, for example, a single-machine or multi-machine terminal, a server or other processing device. The terminal may be a User Equipment (UE) such as a mobile device, a Personal Digital Assistant (PDA), a handheld device, a computing device, a vehicle-mounted device, a wearable device, etc. In some possible implementations, the method may also be implemented by the processor calling a computer-readable instruction stored in the memory. In this embodiment, the model arrangement space is a house layout design drawing. When the user operation includes a drag operation on the capture element, the capture element and the first model move according to the drag operation. As shown in FIG. 2, the method may include the following steps S210 to S230.
Step S210: in response to triggering to arrange a first model on a house layout design drawing, displaying at least one capture element of the first model; where the house layout design drawing includes a first reference line drawn according to a user operation instruction.

The embodiment of the present disclosure may be applied to a tool platform for home decoration design, a user may operate on a visual interactive interface through an electronic device, and the electronic device may move and place the model accurately in response to the user's operation.

In an embodiment of the present disclosure, the house layout design drawing may be a plan image, including but not limited to a top view image, a facade image, and the like. Here, the top view image may be a top view or a ground view of the house layout space; and the facade image may be an image facing a wall in the house layout space. The house layout design drawing may be displayed in the visual interactive interface.

It can be understood that the first model is an object model selected by the user, that is, a model to be moved and placed accurately. Optionally, when the house layout design drawing is a top view image, the first model may include an object model arranged on the ground or the top surface, such as a bed, a sofa, a table, etc. When the house layout design drawing is a facade image, the first model may include an object model that can be arranged on the side wall of the wall space, such as a mural, a hanging lamp, etc. In practical applications, the position of the first model in the house layout design drawing can be determined according to the user operation through the embodiment of the present disclosure.

Optionally, the first model may be included in the house layout design drawing, the user may directly select the first model on the house layout design drawing, and at least one capture element of the first model selected by the user is displayed in the house layout design drawing. Specifically, the house layout design drawing may include a plurality of models to be selected, and the user may select one of the plurality of models to be selected as the first model.

Optionally, the first model may not be included in the house layout design drawing, a model read from a designated path may be used as the first model, and the first model may be displayed in the house layout design drawing. For example, the user may select the first model from the pre-configured model styles displayed, or draw the first model in a third-party software (such as CAD) and store it in the designated path. The user may input the path of the first model, and the electronic device may read the first model according to the input path and use it as the first model of the house layout design drawing.

In an embodiment of the present disclosure, the capture element of the first model may be any point or line segment related to the first model in the house layout design drawing, and the position of the capture element may be on the first model or may not be on the first model. The types, positions and number of capture elements may vary from model to model. Optionally, one part of the capture elements may be some key points, line segments and other elements on the first model, and the other part of the capture elements may be points, line segments and other elements pre-bound with the first model. These capture elements may be on the first model or may not be on the first model. The capture element and the first model may move synchronously, and the electronic device may obtain the relative position relationship between the capture element and the first model, and determine the position of the first model according to the position of the capture element. Optionally, there may be a plurality of capture elements.

In an embodiment of the present disclosure, the house layout design drawing also includes the first reference line, and the position of the first reference line is used as a reference for the precise arrangement of the first model. The first reference line may be drawn by the user on the interactive interface provided by the electronic device. The electronic device may display the first reference line in the visual interactive interface in response to the user's drawing operation.

Exemplarily, the first reference line may be a straight line drawn by the user on the house layout design drawing according to the desired arrangement position, and the straight line does not belong to the model in the house layout design drawing. For example, the first reference line may be a straight line with 2000 mm (millimeter) from the ground in the facade image or a straight line with 1000 mm from the floor cabinet in the top view image, so that the user can arrange the first model at a position with 2000 mm from the ground on a specific facade or at a position with 1000 mm from the floor cabinet on the ground.

Optionally, the first reference line may also be a reference line selected by the user from a plurality of reference lines to be selected on the house layout design drawing. Specifically, the house layout design drawing may include a plurality of pre-drawn reference lines. When arranging the first model, the user may choose to display some of the reference lines and hide some of the reference lines. The first reference line is a displayed reference line, so that the user can use the reference position information provided by the first reference line to arrange the first model to the user's desired position.

Optionally, the first reference line may be drawn by the user at any position in the house layout design drawing, and there is no specific limitation on the length, thickness and shape of the first reference line.
Step S220: in response to detecting a drag operation on a first capture element among the at least one capture element, moving the first capture element and the first model according to a trajectory corresponding to the drag operation and a relative position between the first capture element and the first model.

In an embodiment of the present disclosure, the relative position between the capture element and the first model is fixed. For example, the capture element is an endpoint of an external frame of the first model, or the capture element is an auxiliary line segment outside the first model with 20 mm (millimeter) away from the first model.

In an embodiment of the present disclosure, the user may drag the first capture element to any position on the house layout design drawing. When the user drags the first capture element, the electronic device displays the positions of the first capture element and the first model to the user in real time by detecting the trajectory corresponding to the drag operation of the first capture element and using the trajectory and the relative position between the first capture element and the first model.

It can be understood that the first capture element is a capture element selected by the user from a plurality of capture elements, and the electronic device may determine the first capture element from the plurality of capture elements in response to the user's operation to select from the plurality of capture elements. Optionally, after the first capture element is determined, only the first capture element of the first model may be displayed in the electronic device, and unselected capture elements are hidden.

Optionally, the electronic device may also display the dragging trajectory of the first capture element and the distances from other elements on the house layout design drawing to the user in real time during the drag operation.
Step S230: if a preset adsorption condition is met between the first reference line and the first capture element and an arrangement confirmation instruction input by the user is detected during movement, determining an arrangement position of the first capture element based on a position of the first reference line, and determining an arrangement position of the first model based on the relative position between the first capture element and the first model.

The adsorption condition between the first reference line and the first capture element is a condition pre-configured by the user. In practical applications, the adsorption condition may be that the distance between the first reference line and the first capture element is less than a preset threshold. The electronic device may detect the distance between the first reference line and the first capture element in real time. For example, when the distance between the first reference line and the first capture element is less than 10 px (pixel), the preset adsorption condition is met.

In an embodiment of the present disclosure, the arrangement confirmation instruction is an instruction input by the user to stop the movement of the first capture element, such as a click instruction on the interactive interface. Specifically, the user may drag the first capture element to move on the interactive interface, thereby dragging the first model to move. When the user drags the first capture element and the first model to their desired positions, the user may click to confirm.

According to the embodiment of the present disclosure, if the arrangement confirmation instruction input by the user is detected when the first capture element is dragged and moved to a position at which the preset adsorption condition is met with respect to the first reference line, the first capture element may be adsorbed onto the first reference line.

Exemplarily, the step of determining the arrangement position of the first capture element based on the position of the first reference line may include: if the first capture element is a line segment, determining the arrangement position of the first capture element as a line segment on the first reference line closest to the first capture element; if the first capture element is a point, determining the position of the first capture element as a point on the first reference line closest to the first capture element. It can be understood that, when the position of the first capture element is adsorbed onto the first reference line, the arrangement position of the first model can be determined accordingly according to the relative position between the first capture element and the first model. Afterwards, the first model may be displayed on the house layout design drawing according to the arrangement position of the first model.

It can be understood that, when it is detected that the preset adsorption condition is met between the first reference line and the first capture element but no arrangement confirmation instruction input by the user is detected, the first capture element and the first model may continue to be moved according to the trajectory corresponding to the drag operation and the relative position between the first capture element and the first model until the arrangement confirmation instruction input by the user is detected.

It should be noted that the user may drag the first capture element to any position on the house layout design drawing. If the preset adsorption condition is met between the first capture element and the first reference line on the house layout design drawing when the arrangement confirmation instruction is detected, the first capture element may be adsorbed onto the first reference line. If the preset adsorption condition is not met between the first capture element and any reference line on the house layout design drawing when the arrangement confirmation instruction is detected, the real-time position of the first capture element when the arrangement confirmation instruction is detected or the position of another point (such as a point on another model, etc.) at which the preset adsorption condition is met with respect to the first capture element may be determined as the arrangement position of the first capture element, and the arrangement position of the first model may be determined accordingly.

For example, when the first capture element is a capture point, the user may use a point on the first reference line as a reference point (such as a point of intersection between the first reference line and the second reference line), move the first capture element close to the reference point, and click to confirm when observing that the two points coincide. It can be understood that the capture point and the reference point should meet the preset adsorption condition when the user observes that the two points coincide. At this time, the electronic device detects the arrangement confirmation instruction input by the user, and then may determine the arrangement position of the capture point to be on the reference point (that is, the capture point is adsorbed onto the position of the reference point).

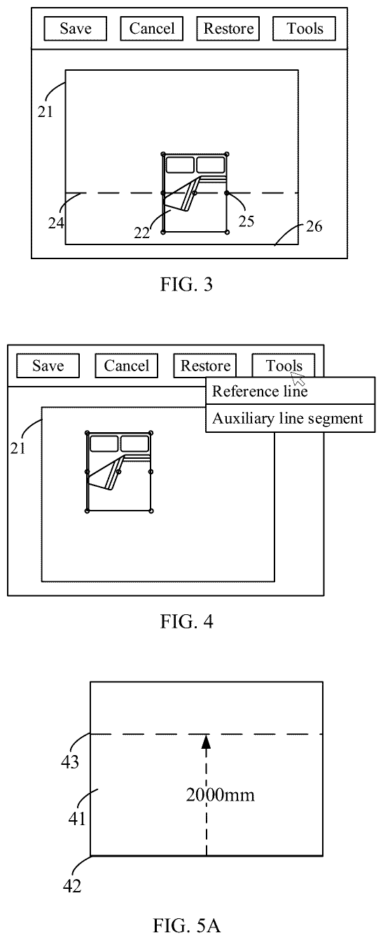

As shown in FIG. 3, in the house layout design drawing 21, the first reference line 24 is a straight line with 1500 mm away from the wall 26, and the first model 22 is a bed. If the user wishes to arrange the first model 22 at a position on the center line with 1500 mm away from the wall 26, the user may select the midpoint of the right frame line of the first model 22 as the first capture element 25, and drag and move the first capture element 25 and the first model 22 close to the first reference line 24 until the first capture element 25 and the first reference line 24 substantially coincide. At this time, confirmation is clicked, and then the electronic device may determine that the arrangement confirmation instruction input by the user is detected when the first capture element 25 and the first reference line 24 meet the preset adsorption condition. Based on this, the electronic device adsorbs the first capture element 25 and the first reference line 24 to thereby determine the arrangement position of the first model 22. It can be seen that, in the above process, the user can confirm the position with 1500 mm away from the wall 26 via the reference line 24, and arrange the first model 22 at the desired position by adsorbing the capture element. For example, the first capture element can be arranged on the reference line when dragged near the first reference line, without requiring the user to carefully observe the position parameters and accurately move the model to a specific position.

According to the technical solution in the embodiment of the present disclosure, the reference line drawn according to the user operation instruction can be displayed on the house layout design drawing, and the user can move the capture element and correspondingly move the first model through the drag operation on the capture element of the first model. The user only needs to move the capture element to a position at which the adsorption condition is met with respect to the reference line according to requirements, so that the arrangement position of the first capture element can be accurately determined based on the position of the reference line, and the arrangement position of the first model can be determined based on the relative position between the capture element and the first model. Therefore, the model can be moved and placed accurately, and the efficiency of model arrangement can be improved, so that the solution of the present disclosure can be applied to the actual model arrangement link to realize accurate model arrangement in various scenarios.

In some embodiments, the method for determining model arrangement information further includes a manner to draw the first reference line. Specifically, the method for determining model arrangement information may further include:
in a reference line drawing mode, in response to detecting a datum point confirmation instruction on the house layout design drawing, determining reference line datum information based on a detection position of the datum point confirmation instruction, and starting to detect a drawing confirmation instruction on the house layout design drawing; and
generating the first reference line on the house layout design drawing based on the reference line datum information and position information indicated by the drawing confirmation instruction.

In an embodiment of the present disclosure, the user may enter the reference line drawing mode to draw the reference line on the house layout design drawing. As shown in FIG. 4, a toolbar and the house layout design drawing 21 are displayed on the interactive interface. The user may click the button “Tools” on the toolbar to bring up a drop-down window containing the entry “Reference Line” for the reference line drawing mode. The user may click “Reference Line” to enter the reference line drawing mode.

After entering the reference line drawing mode, the electronic device firstly detects the datum point confirmation instruction. Optionally, the datum point confirmation instruction may be the first click instruction detected after entering the reference line drawing mode. The datum point confirmation instruction may be used to specify a datum point on the house layout design drawing. Optionally, if the preset adsorption condition is met between the detection position of the datum point confirmation instruction (i.e., the position clicked by the user) and a non-blank point on the house layout design drawing, then the datum point specified by the datum point confirmation instruction is the non-blank point; if the preset adsorption condition is not met between the detection position of the datum point confirmation instruction and any element on the house layout design drawing, then the datum point specified by the datum point confirmation instruction is a blank point at the detection position.

In an embodiment of the present disclosure, the reference line datum information is used as the datum for drawing a straight line. Optionally, the reference line datum information may be the datum point mentioned above, or may be a position having a certain positional relationship with the datum point mentioned above.

It can be understood that the electronic device can detect the drawing confirmation instruction after determining the reference line datum information. The drawing confirmation instruction may be a click instruction on the house layout design drawing, such as the first click instruction after the datum point confirmation instruction; or may be position information input by the user, such as distance, coordinates and other parameters. The drawing confirmation instruction is used to confirm that the user has finished drawing and to indicate position information. If the drawing confirmation instruction is a click instruction, the position information indicated by the drawing confirmation instruction is the detection position of the drawing confirmation instruction, or the position of a point that meets the preset adsorption condition with respect to the detection position. If the drawing confirmation instruction is the position information input by the user, the position information indicated by the drawing confirmation instruction is the position information input by the user.

The electronic device may determine the position information indicated by the drawing confirmation instruction, so as to generate the first reference line based on the datum point and the position information indicated by the drawing confirmation instruction.

Optionally, the reference line datum information and the position information indicated by the drawing confirmation instruction do not overlap, or are located at different positions in the house layout design drawing. In addition, the reference line datum information and the position information indicated by the drawing confirmation instruction may be located at any positions in the house layout design drawing, and the generated first reference line may also be located at any position in the house layout design drawing. Optionally, there is no specific limitation on the length, thickness and shape of the first reference line.

According to the technical solution in the embodiment of the present disclosure, the user can enter the reference line drawing mode to draw the reference line on the house layout design drawing. In the reference line drawing mode, the reference line can be accurately generated according to the reference line datum information and the position information indicated by the drawing confirmation instruction, thereby meeting the user's various drawing requirements on the reference line and further improving the accuracy of the model arrangement.

In some embodiments, when the datum point indicated by the datum point confirmation instruction is located on a linear element in the house layout design drawing, the reference line datum information is the linear element. Accordingly, the step of generating the first reference line based on the reference line datum information and the position information indicated by the drawing confirmation instruction includes:
generating the first reference line parallel to the linear element on the house layout design drawing according to a distance value included in the drawing confirmation instruction and/or a detection position of the drawing confirmation instruction.

According to the above embodiments, when the datum point indicated by the datum point confirmation instruction is on a linear element, such as on a frame line or a wall of a model, the reference line datum information is the linear element. That is to say, the reference line is drawn based on the linear element. The generated first reference line is a straight line parallel to the linear element.

Optionally, the drawing confirmation instruction may include a distance value input by the user. The electronic device may generate, according to the distance value, the first reference line of which the distance from the linear element is the distance value and which is parallel to the linear element.

As shown in FIG. 5A, the house layout design drawing is a facade image. When the user clicks on the ground 42 (which is a line, i.e., a linear element, in the facade image) in the house layout design drawing 41, the datum point indicated by the datum point confirmation instruction is located on the ground 42, and the reference line datum information is the ground 42. At this time, the user may input a distance value, such as 2000 mm (two meters), and then the electronic device may generate a straight line with two meters from the ground 42 and parallel to the ground as the first reference line 43. In this way, when the user needs to arrange the object model at a height of two meters from the ground, the first reference line may be used to achieve precise arrangement.

Optionally, the drawing confirmation instruction may also be a click instruction detected on the interactive interface. The electronic device may also generate, according to a position indicated by the click instruction (the detection position of the click instruction or the adsorption position), the first reference line that penetrates through this position and is parallel to the linear element. The electronic device may generate, according to the position indicated by the click instruction, the first reference line that passes through this position and is parallel to the linear element. For example, in the example as shown in FIG. 5A, after determining that the ground 42 is the reference line datum information, the user may move the input cursor to the position above the ground 42 in the house layout design drawing 41, and the distance between the current cursor and the ground 42 may be displayed in real time on the interactive interface to assist the user in confirmation. When the user clicks a certain position, a straight line parallel to the linear element at this position will be generated as the first reference line 43.

Optionally, the linear element may be any line segment in the house layout design drawing before the first reference line is drawn. Specifically, the linear element in the house layout design drawing include at least one of: a second reference line, a line segment of a house layout component, or an external frame line of a second model arranged on the house layout design drawing.

It can be understood that the second reference line may be a reference line in the house layout design drawing before the first reference line is drawn, or the second reference line may be a straight line drawn in the above manner. The line segment of the house layout component may be a line segment on the house layout structure in the house layout design drawing, for example, the line segment of the house layout component may be a wall in the house layout design drawing. The external frame line of the second model arranged on the house layout design drawing may be any line segment on the external frame line of the second model in the house layout design drawing before the first reference line is drawn. The second model may be the first model in steps S210 to S230, or may be a model other than the first model in steps S210 to S230.

According to the technical solution in the embodiments of the present disclosure, the user can generate the reference line based on the linear element in the house layout design drawing by setting the distance value and/or selecting the position of the drawing confirmation instruction, further meeting the user's various drawing requirements on the reference line, having wide versatility, and supporting the user to customize the position of the reference line. It can be understood that the above manner to draw the reference line is to generate the reference line by offsetting the linear element, so this manner can be called offset creation.

In some embodiments, when the datum point indicated by the datum point confirmation instruction is not located on a linear element in the house layout design drawing, the reference line datum information is the datum point; and the first reference line penetrates through the datum point and the position information indicated by the drawing confirmation instruction.

In the embodiments of the present disclosure, the position of the datum point confirmed by the user may not be located on the linear element in the house layout design drawing, the datum point indicated by the datum point confirmation instruction may be used as one point that the first reference line needs to penetrate through, and the position information indicated by the drawing confirmation instruction may be used as the other point that the first reference line needs to penetrate through, to generate the first reference line penetrating through the two points.

As shown in FIG. 5B, after entering the reference line drawing mode, the user firstly clicks a position on the house layout design drawing 41 to indicate the datum point 431. Since the datum point 431 is not on any linear element, the electronic device will detect the next point 432 to generate a straight line penetrating through the datum point 431 and the next point 432 as the first reference line 43.

According to the technical solution in the embodiments of the present disclosure, the first reference line can be generated in the house layout design drawing in response to the detected positions of the datum point confirmation instruction and the drawing confirmation instruction in the house layout design drawing, further meeting the user's various drawing requirements on the reference line, having wide versatility, and supporting the user to customize the position of the reference line. It can be understood that the above manner to draw the reference line is to generate the reference line based on two points, so this manner can be called two-point creation.

In some embodiments, the at least one capture element includes at least one of: an element on an external frame of the first model, a point on a mesh surface of the first model, a key point determined when the first model is modeled, an auxiliary line segment of the first model, or a key point on the auxiliary line segment.

It can be understood that the element on the external frame of the first model may be a point (such as endpoint, midpoint, etc.) or line segment on the external frame surrounding the first model, and the external frame may be a rectangular external frame. Regarding the point on the mesh surface of the first model, the mesh surface may be a data structure for modeling the first model. For example, the point on the mesh surface of the first model may be a point on a polygonal mesh of the first model. The key point determined when the first model is modeled may be a specified point on the first model during modeling. The auxiliary line segment of the first model may be a line segment related to the first model drawn by the user and used to increase the capture elements of the first model. The key point on the auxiliary line segment is, for example, an endpoint, a midpoint or the like of the auxiliary line segment.

According to the technical solution in the embodiments of the present disclosure, there are a large number and types of capture elements available for the user to choose, the positions of the capture elements are highly precise, and the versatility is wide, further improving the accuracy of model arrangement, and realizing accurate model arrangement in various scenarios.

In some embodiments, the method for determining model arrangement information may further include a manner to draw the auxiliary line segment of the first model. Specifically, the method for determining model arrangement information may further include:
in an auxiliary line drawing mode, detecting a start point confirmation instruction and an end point confirmation instruction detected on the house layout design drawing;
generating the auxiliary line segment based on a start point indicated by the start point confirmation instruction and an end point indicated by the end point confirmation instruction; and
binding the auxiliary line segment with the first model.

In the embodiments of the present disclosure, the user may enter the auxiliary line drawing mode to draw the auxiliary line segment on the house layout design drawing. As shown in FIG. 4, the user may click “Tools” to bring up a drop-down window, and click “Auxiliary Line Segment” in the drop-down window to enter the auxiliary line drawing mode. The user may issue the start point confirmation instruction and the end point confirmation instruction, that is, the user specifies two points on the house layout design drawing in the electronic device as the start point and the end point of the auxiliary line segment. The electronic device may determine the positions of the start point and the end point, and connect the start point with the end point to obtain the auxiliary line segment.

It can be understood that the auxiliary line segments are used to increase the capture elements of the first model. All or part of the auxiliary line segments bound with the first model, as well as key points (which may be any points, endpoints, midpoints, etc.) on the auxiliary line segments may be used as capture elements of the first model.

It can be understood that the start point indicated by the start point confirmation instruction and the end point indicated by the end point confirmation instruction may be located at any positions in the house layout design drawing, and the generated auxiliary line segment may also be located at any position in the house layout design drawing. Optionally, there is no specific limitation on the length, thickness and shape of the auxiliary line segment, and the auxiliary line segment may be drawn before or after the reference line.

It can be understood that the user needs to select one model on the house layout design drawing to bind with the auxiliary line segment. This model may be the first model in steps S210 to S230, and the auxiliary line segment is bound with this model, that is, a relative position relationship between the auxiliary line segment and the model is established, so that the model can move according to the relative position relationship between the auxiliary line segment and the model when the auxiliary line segment is dragged to move, realizing synchronous movement of the auxiliary line segment and the model.

As shown in FIG. 6, the user may specify a start point 53 and an end point 55 on the house layout design drawing 51, the start point 53 and the end point 55 may be connected to generate an auxiliary line segment 56, and the auxiliary line segment 56 may be bound with the first model 52 on the house layout design drawing 51. In this way, when the user chooses to move the first model 52 (i.e., arrange the first model), the auxiliary line segment 56 may be displayed for the user to select as the first capture element.

According to the technical solution in the embodiments of the present disclosure, the user can enter the drawing mode of the auxiliary line segment to draw the auxiliary line segment on the house layout design drawing. In the drawing mode of the auxiliary line segment, the auxiliary line segment can be accurately generated according to the start point and end point determined by the user, thereby increasing the capture elements of the first model, improving the position precision of the capture elements, having wide versatility, further improving the accuracy of model arrangement, and realizing accurate model arrangement in various scenarios.

In some embodiments, the start point confirmation instruction includes a click confirmation instruction for the start point, or a confirmation instruction for adsorbing a point on the house layout design drawing as the start point; and
the end point confirmation instruction includes a click confirmation instruction for the end point, or a confirmation instruction for adsorbing a point on the house layout design drawing as the end point.

In an embodiment of the present disclosure, the electronic device may detect the positions of the start point confirmation instruction and the end point confirmation instruction on the house layout design drawing. When the position of the start point confirmation instruction and/or the end point confirmation instruction on the house layout design drawing and a non-blank point (for example, a point on a linear element, an endpoint of a model, etc.) on the house layout design drawing meet the adsorption condition, the start point and/or the end point may be adsorbed to the position of the point, that is, the position of the start point and/or the end point may be the position of the non-blank point on the house layout design drawing. When the position of the start point confirmation instruction and/or the end point confirmation instruction on the house layout design drawing and a point on the house layout design drawing do not meet the adsorption condition, the position of the start point confirmation instruction and/or the end point confirmation instruction on the house layout design drawing may be used as the start point and/or the end point of the auxiliary line segment. Optionally, the adsorption condition may be that the distance between the position of the start point confirmation instruction and/or the end point confirmation instruction on the house layout design drawing and a point on the house layout design drawing is less than a preset threshold.

As shown in FIG. 6, if the adsorption condition is meet between the detection position of the start point confirmation instruction on the house layout design drawing 51 and the point 54 on the external frame of the first model 52, then the point 54 on the external frame of the first model 52 is adsorbed as the start point 53. If the adsorption condition is not meet between the detection position of the end point confirmation instruction on the house layout design drawing 51 and the point 54 closest thereto, then the position of the end point 55 is the detection position of the end point confirmation instruction on the house layout design drawing 51.

According to the technical solution in the embodiments of the present disclosure, the start point and the end point can be located at the detection position of the user instruction or adsorbed to a point on the house layout design drawing, improving the position accuracy of the start point and the end point and generating the auxiliary line segment more accurately.

In some embodiments, the above step S210 (in response to triggering to arrange the first model on the house layout design drawing, displaying at least one captured element of the first model) may include:
in response to triggering to arrange a first model on a house layout design drawing, determining a type of a capture element to be displayed according to size information of an external frame of the first model; and
displaying at least one capture element of the first model according to the type of the capture element to be displayed.

Correspondingly, before step S220, the method for determining model arrangement information may further include: in response to a selection operation of the user in at least one capture element, determining a first capture element in the at least one capture element.

In an embodiment of the present disclosure, the type of the capture element to be displayed may be determined according to the size information (such as area, length, width, etc.) of the external frame of the first model displayed in the electronic device. Optionally, when the size information of the external frame of the first model is relatively large, the electronic device may display a larger number of capture elements of the first model, and thus may display capture elements of richer types. Alternatively, when the size information of the external frame of the first model is relatively small, the electronic device may only display a small number of capture elements of the first model with fewer types, so that the user can accurately select the first capture element.

It can be understood that the external frame of the first model is a rectangle surrounding the first model, and the size information of the external frame of the first model may be determined by the area of the first model, the shape of the first model, and the scaling ratio of display of the electronic device. When the user thinks that the number of capture elements is too many or too few, the user may adjust the scaling ratio of display of the electronic device to reduce or increase selections of capture elements.

In an embodiment of the present disclosure, the electronic device determines the type of the capture element to be displayed according to the size information of the external frame, and the user may select one of the displayed capture elements as the first capture element. The appropriate number of capture elements can be displayed by controlling the capture element type, avoiding the problem of too many capture elements to be accurately selected or too few capture elements to be accurately arranged.

In some embodiments, when the size information of the external frame of the first model is greater than a preset first threshold, the type of the capture element to be displayed includes at least one of: an element on the external frame of the first model, a point on a mesh surface of the first model, a key point determined when the first model is modeled, an auxiliary line segment of the first model, or a key point on the auxiliary line segment.

It can be understood that the first threshold may be pre-configured data. When the size information of the external frame of the first model is greater than the first threshold, the electronic device may display all capture elements that can be displayed, that is, the element on the external frame of the first model, the point on the mesh surface of the first model, the key point determined when the first model is modeled, the auxiliary line segment of the first model, and the key point on the auxiliary line segment, so that the user can conveniently and accurately select the first capture element.

Specifically, in some embodiments, when the size information of the external frame of the first model is less than the preset first threshold, the type of the capture element to be displayed includes at least one of: an element on the external frame of the first model, and an auxiliary line segment of the first model.

Optionally, when the size information of the external frame of the first model is less than the preset first threshold and larger than a preset second threshold, the type of the capture element to be displayed includes an element on the external frame of the first model, and an auxiliary line segment of the first model. When the size information of the external frame of the first model is less than the preset second threshold, the type of the capture element to be displayed includes an element on the external frame of the first model.

It can be understood that the second threshold may also be pre-configured data. When the area of the external frame of the first model is less than the first threshold and greater than the preset second threshold, the electronic device may display some capture elements, that is, the element on the external frame of the first model and the auxiliary line of the first model, so that the user can conveniently and accurately select the first capture element.

It can be understood that, when the area of the external frame of the first model is less than the first threshold, the displayed distance between some capture elements will be relatively short due to the small area of the external frame of the first model, making it difficult for the user to distinguish. Therefore, the capture elements that the electronic device can display are at least one element on the external frame of the first model, so that the user can conveniently and accurately select the first capture element.

It can be seen that, according to the technical solution in the embodiments of the present disclosure, the capture elements of the first model can be dynamically displayed in the electronic device, so that the user can conveniently and accurately select the first capture element, improving the user's operating experience and thus improving the efficiency and accuracy of the model arrangement.

In some embodiments, in an arrangement off mode, the at least one capture element includes an element on the external frame of the first model.

In the embodiments of the present disclosure, the user may select and enter the arrangement off mode, the capture elements that the electronic device can display are elements (lines, points, etc.) on the external frame of the first model, and the user may select an element on the external frame as the first capture element.

According to the technical solution in the embodiments of the present disclosure, the capture elements that can be adsorbed to the first reference line include elements on the external frame of the first model in the arrangement off mode, so that the model can be accurately moved and arranged based on the elements on the external frame.

Correspondingly, in some embodiments, in an arrangement on mode, the at least one capture element includes at least one of: an element on the external frame of the first model, a point on a mesh surface of the first model, a key point determined when the first model is modeled, an auxiliary line segment of the first model, or a key point on the auxiliary line segment.

In the embodiments of the present disclosure, the user may select and enter the arrangement on mode, the electronic device may display richer capture elements than those in the arrangement off mode, and the number and types of capture elements in the arrangement on mode are increased, thereby improving the position precision of the capture elements so that the model can be moved and placed accurately.

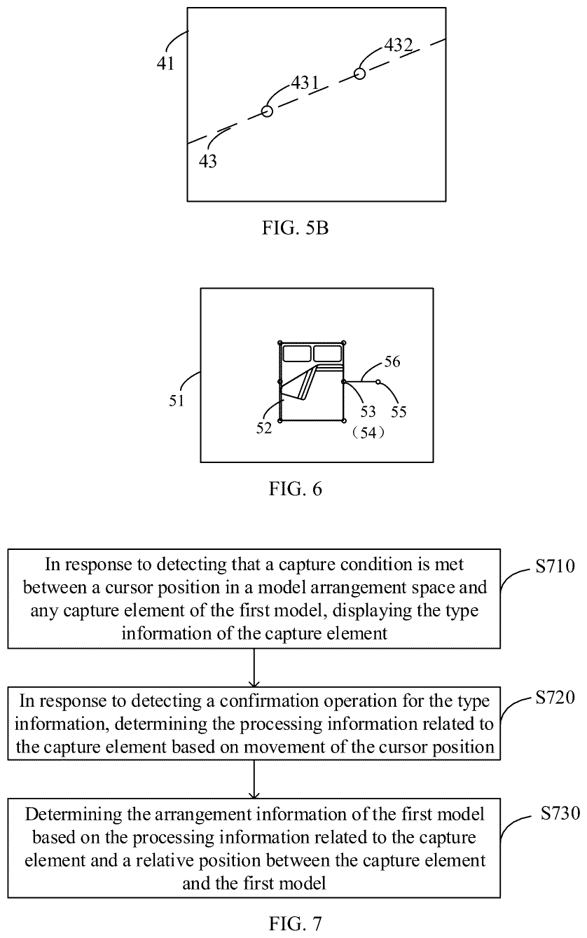

FIG. 7 shows a schematic diagram of a method for controlling model operation according to another embodiment of the present disclosure. This method may be applied to an electronic device. In some possible implementations, the method may also be implemented by the processor calling a computer-readable instruction stored in the memory. As shown in FIG. 7, the method may include the following steps S710 to S730.
S710: in response to detecting that a capture condition is met between a cursor position in a model arrangement space and any capture element of the first model, displaying the type information of the capture element;
S720: in response to detecting a confirmation operation for the type information, determining the processing information related to the capture element based on movement of the cursor position; and
S730: determining the arrangement information of the first model based on the processing information related to the capture element and a relative position between the capture element and the first model.

Here, the cursor position in the model arrangement space is the current input position moving along with the user's operation, such as the mouse position. In an embodiment of the present disclosure, the capture condition may be related to the distance between the cursor position and the position of the capture element. Exemplarily, the capture condition may be that the distance between the cursor position and the position of the capture element is less than a first value. Here, the first value may be a preset threshold, or a value calculated based on relevant dimensions of the first model, such as one tenth or one fifth of the first model. Based on this, the capture condition may be met when the user controls the cursor position to be close to any capture element of the first model.

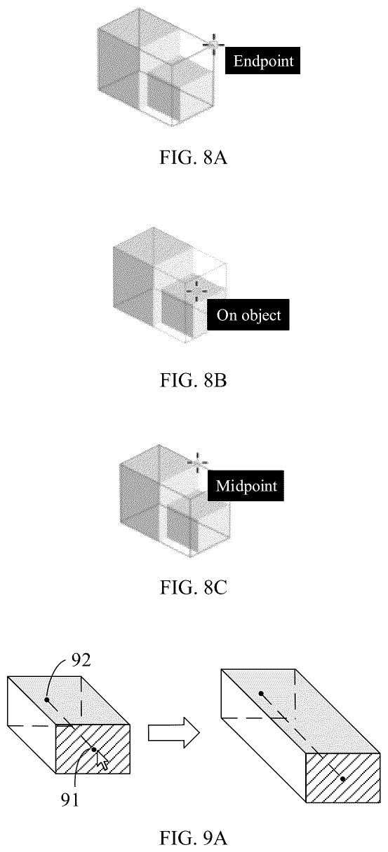

According to the above step S710, the type information of the capture element is displayed when the capture condition is met between the cursor position and any capture element of the first model. FIGS. 8A to 8C show several schematic diagrams of displaying the type information of the capture element. Exemplarily, the type of the capture element may include: an endpoint (a vertice) of a bounding box (or a bounding frame, an external frame) of the model, a point on a surface of the model, or a midpoint of an edge on the bounding box of the model. As shown in FIG. 8A, when the capture condition is met between the cursor position and an endpoint, the type information “endpoint” is displayed. As shown in FIG. 8B, when the capture condition is met between the cursor position and a point on a surface of the model, the type information “on object” is displayed. As shown in FIG. 8C, when the capture condition is met between the cursor position and a midpoint of an edge on the bounding box of the model, the type information “midpoint” is displayed.

When the type information of any element is displayed, if a confirmation operation (such as a mouse click) input by the user is detected, the confirmation operation can be considered as the confirmation operation for the type information. In an embodiment of the present disclosure, the confirmation operation is used to confirm the capture element corresponding to the type information as the capture element to be operated. At this time, the processing information related to the capture element may be determined based on the movement of the cursor position. In this way, the user can input the processing information related to the capture element by moving the cursor position.

Exemplarily, the processing information related to the capture element may include one or more of: the position of the capture element, and positions of points, lines or surfaces with the capture element as the datum. For example, the user may move the cursor position to drag the capture element, thereby moving the capture element to move the first model, or scale the line or axis to which the capture element belongs to scale the first model. For another example, the user may move the cursor position to determine the positions of some points, lines or surfaces with the capture element as the datum, thereby inputting the positions of these points, lines or surfaces.

When the electronic device obtains the processing information related to the capture element, there is a fixed relative position between the capture element and the first model (for example, the capture element is an endpoint of the 2D external frame/3D bounding box of the first model, or the capture element is an auxiliary line segment outside the first model with 20 mm away from the first model), so the electronic device may determine the arrangement information of the first model based on the processing information and the relative position. For example, the electronic device may determine the arrangement position or scaling parameter of the first model based on the movement position of the capture element and the relative position. For another example, the electronic device may complete other arrangement operations on the first model based on the information of points, lines and surfaces with the capture element as the datum, the position of the capture element, and the relative position between the capture element and the first model.

According to the method in the embodiment of the present disclosure, when the cursor position moves in the model arrangement space, if any capture element of the first model is captured, the type information is displayed to assist the user in confirming the capture element, so that the relevant processing information can be determined based on the capture element confirmed by the user, and the arrangement information of the first model can be determined based on the processing information, to complete the arrangement of the first model. Therefore, the problem of difficulty in accurate capture when there are many capture elements can be solved, thereby supporting the setting of multiple types and a large number of capture elements to achieve accurate capture and adsorption in the model arrangement space, and facilitating the accurate arrangement of the model. For example, for the first model, a point on the mesh surface (Mesh) and an endpoint of the bounding box close to this point may be used as capture elements. When triggering the arrangement of the first model, the type information prompt can enable the user to accurately select the point he wants to capture, so that the position of the point can be aligned with the position of a specific point, line or surface in the model arrangement space, thereby improving the accuracy of the arrangement.

In some embodiments, the method for controlling model operation further includes: when the cursor position in the model arrangement space and a capture element invisible from a current viewing angle of a camera meet the capture condition, reducing the display transparency of the first model to display the capture element.

It can be understood that the corresponding house layout space and model are displayed based on a certain viewing angle in the model arrangement space. For example, the viewing angle may be a top viewing angle or a viewing angle toward a facade in the 2D space. The viewing angle may be associated with the parameters of a virtual camera in the 3D space. For example, the viewing angle is the shooting angle of the virtual camera. The viewing angle of the virtual camera to observe the model arrangement space may be changed by adjusting the distance, the orientation angle or the like between the virtual camera and the model arrangement space or adjusting the external parameters of the virtual camera; or, the parameters and viewing angle of the virtual camera may be changed by dragging the house layout space on the interactive interface. In the embodiments of the present disclosure, the current viewing angle of the camera may be understood as the viewing angle to currently present the 3D space.

In actual applications, at a specific viewing angle, some information of the model may be invisible so that some capture elements may be invisible, so the user cannot accurately select or confirm these capture elements and thus cannot achieve the precise arrangement related to these capture elements. In the embodiments of the present disclosure, when the cursor position and the invisible capture element meet the capture condition, the display transparency of the first model is reduced to display the capture element invisible from the current viewing angle of the camera, so that the user can confirm whether the capture element invisible from the current viewing angle of the camera is the capture element he expects to select, thereby satisfying the precise arrangement requirement of the user.

Optionally, operations on each model in the model arrangement space may be performed in a variety of modes, such as movement mode, scaling mode, copy mode, rotation mode, and the like. The electronic device may support mode switching in a variety of ways, such as switching through a shortcut key, switching by selecting in a right-click drop-down menu at any blank point in the model arrangement space, or switching through a toolbar or tab. In different modes, the same operation of the user may correspond to different processing information. For example, the cursor movement in the movement, scaling and copy modes may correspond to the movement of the capture element, and the cursor movement in other modes may be to determine other points, lines or surfaces with the capture element as the datum.

In some embodiments, the processing information related to the capture element includes: a movement position of the capture element in the movement mode. Correspondingly, the above-mentioned step S730 of determining the arrangement information of the first model based on the processing information related to the capture element and the relative position between the capture element and the first model includes: determining a movement position of the first model based on the movement position of the capture element and the relative position between the capture element and the first model.

That is to say, in the movement mode, the movement of the cursor position is used to control the movement position of the capture element, that is, the capture element moves with the cursor position, and the first model moves relatively with the capture element, so that the movement position of the first model can be determined by moving the cursor position. The above method supports setting various types of capture elements and can thus support using various types of capture elements to drive the movement of the first model, realizing the accurate movement of the first model in the model arrangement space.

Optionally, in the movement mode, if a confirmation operation for the movement position of the capture element is detected, the movement position of the capture element and the movement position of the first model are used as their arrangement positions, that is, the first model is arranged at the position corresponding to the confirmation operation. Optionally, if the movement of the cursor position is implemented by long-pressing and dragging after clicking confirmation, the confirmation operation may be releasing the drag, such as releasing the mouse. If the movement of the cursor position is implemented by releasing after clicking confirmation, the confirmation operation may be clicking confirmation again.

As an application example, the movement of the first model may be achieved by the following process: the user moves the mouse, and the mouse captures and adsorbs a capture element (such as a point) on the first model based on the user's confirmation operation as the start point or datum point for movement. The first model and the datum point maintain relative positions and move with the mouse. Optionally, in the above movement mode, the moving distance may be displayed on the moving track of the capture element, and the moving straight-line distance may be modified by inputting parameters. When the user clicks the mouse, the first model being moved is dropped to complete the precise movement. When the movement is completed, the user may activate other functions/modes through the keyboard, mouse, etc. to terminate the movement mode. If the movement mode is not terminated, the user may move the mouse to the position of another model to move another model.

In some embodiments, the processing information related to the capture element includes: a movement position of the capture element in the copy mode. Correspondingly, the above-mentioned step S730 of determining the arrangement information of the first model based on the processing information related to the capture element and the relative position between the capture element and the first model includes: in response to detecting a confirmation operation for the movement position of the capture element, determining the movement position of the capture element as a copy end point; and determining a copy position of the first model based on the copy end point and the relative position between the capture element and the first model.

That is to say, in copy mode, the movement of the cursor position is used to control the movement position of the capture element, that is, the capture element moves with the cursor position, and the first model does not move relatively with the capture element. When the cursor position moves to the position confirmed by the user through the confirmation operation (such as clicking), the movement position of the capture element at this time is the copy end point (that is, the datum point for copying). The copy position of the first model can be determined based on the copy end point and the relative position between the capture element and the first model. The method for controlling model operation may further include: displaying a copied object of the first model at the copy position.

The above method supports setting various types of capture elements and can thus support using various types of capture elements to accurately copy the first model in the model arrangement space.

Optionally, if the movement of the cursor position is implemented by long-pressing and dragging after clicking confirmation, the confirmation operation for the movement position of the capture element may be releasing the drag, such as releasing the mouse. If the movement of the cursor position is implemented by releasing after clicking confirmation, the confirmation operation for the movement position of the capture element may be clicking confirmation again.

As an application example, the copying of the first model may be achieved by the following process: the user activates the copy mode and then moves the mouse to the first model to be copied, to capture and adsorb a capture element on the first model based on the user's confirmation operation as a start point for copying; and the user moves the mouse and selects an end point, and completes the precise copying of the first model by clicking confirmation. When the copying is completed, the user may activate other functions/modes through the keyboard, mouse, etc. to terminate the copy mode.

Optionally, the method for controlling model operation may support continuous copying. Specifically, in some embodiments, after the copied object of the first model is displayed at the copy position, if the continuous copying preference is turned on, the movement position of the capture element continues to be determined based on the movement of the cursor position; and when a confirmation operation for the movement position of the capture element is detected, the movement position of the capture element is determined as the next copy end point and thus the next copy position of the first model is determined, and the next copied object of the first model is displayed at this copy position. Optionally, if the continuous copying preference is not turned on, a capture element adsorbed onto the next model may be captured by moving the cursor position, to copy the next model.

In some embodiments, the processing information related to the capture element includes: a movement position of the capture element in the scaling mode. Correspondingly, the above-mentioned step S730 of determining the arrangement information of the first model based on the processing information related to the capture element and the relative position between the capture element and the first model includes: determining a scaling parameter of the first model based on the movement position of the capture element and the relative position between the capture element and the first model.

That is to say, in the scaling mode, the movement of the cursor position is used to control the movement position of the capture element, that is, the capture element moves with the cursor position, and the first model is scaled along with the capture element. When the cursor moves to a position confirmed by the user through the confirmation operation, another point on the first model is used as datum, the scaling parameter is determined based on this point and the movement position of the capture element, and then the first model is scaled according to the scaling parameter.

In some embodiments, the scaling parameter may include a scaling ratio. Optionally, the electronic device may determine the scaling ratio of the first model based on a ratio of distances between another point on the first model and the capture element before and after the capture element is moved (ie, before and after scaling).

In some embodiments, different types of capture elements may correspond to different scaling types. The method for controlling model operation may further include: displaying the scaled first model based on a scaling type corresponding to the type information of the capture element and the scaling parameter.

Optionally, the type information of the capture element may correspond to two or more scaling types, and the scaling type corresponding to the type information may be switched by a shortcut key.

Exemplarily, the scaling types may include coaxial scaling, proportional scaling, and non-proportional scaling. The type information of the capture element may include a vertice (an endpoint) of a bounding box of the first model, and a center point of each plane on the bounding box. Here, the vertice of the bounding box of the model corresponds to proportional scaling and non-proportional scaling; and the center point of each plane on the bounding box of the model corresponds to coaxial scaling and proportional scaling.

To facilitate understanding of the scaling types described above, specific application examples are provided below by accompanying drawings.

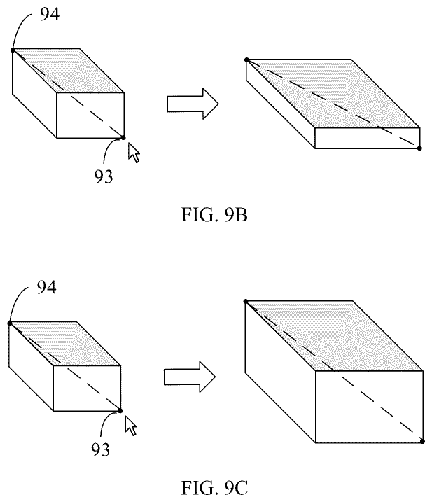

FIG. 9A shows a schematic diagram of coaxial scaling. When the type information of the capture element meeting the capture condition is the center point 91 on the plane on the bounding box of the model (hereinafter referred to as “the plane”), the first model may be coaxially scaled. As shown in FIG. 9A, the coaxial scaling is scaling in the normal direction of the plane, and the first model is scaled only in the normal direction of the plane as the capture element moves. In the case of coaxial scaling, the scaling ratio may be a ratio of distances between the center point 91 on the plane and the center point 92 of another plane opposite to the plane on the bounding box of the model before and after scaling.

FIG. 9B shows a schematic diagram of non-proportional scaling. When the type of the capture element is the vertex 93 of the bounding box of the model, the first model may be non-proportionally scaled. As shown in FIG. 9B, non-proportional scaling is performed for different directions, and the scaling ratios in different directions are determined based on the position (including coordinates in different directions) of the captured vertex 93 and the position (also including coordinates in different directions) of another vertex 94 opposite to the captured vertex 93 on the bounding box of the model, so that the first model can be scaled based on different scaling ratios in different directions.

FIG. 9C shows a schematic diagram of proportional scaling. When the type of the capture element is the vertex 93 of the bounding box of the model or a center point on a plane on the bounding box of the model, the first model may be proportionally scaled. Specifically, the same type of capture elements may correspond to multiple scaling types by switching the scaling type (for example, holding down the shift key on the keyboard to switch). In the case of proportional scaling, the capture element can only be moved in the diagonal direction of the bounding box, and the sizes of the first model in all directions are proportionally scaled as the capture element moves.

In some embodiments, the above method further includes: in the scaling mode, in response to detecting in the model arrangement space that the capture condition is met between the cursor position and any capture element of the first model, displaying a scaling handle based on the type information of the capture element; where the scaling handle is used to prompt the scaling type corresponding to the type information of the capture element.

Optionally, the scaling handle may be a connecting line between the capture element and another point on the bounding box of the model.

Exemplarily, as shown in FIG. 9A, when the type information of the capture element is the center point 91 on one plane on the bounding box of the model, the scaling handle may be a connecting line between the center point 91 and the center point 92 on another opposite plane on the bounding box of the model.

Exemplarily, as shown in FIG. 9B, when the type of the capture element is the vertex 93 of the bounding box of the model, the scaling handle may be a connecting line between the vertex 93 and another vertex 94 of the diagonal line on bounding box of the model.

By displaying the scaling handle, the size of the first model and the stretching change of the scaling handle may assist the user in confirming whether the scaling type is the type expected by the user during the movement of the cursor, thereby facilitating the user to achieve accurate scaling.

As an application example, the scaling of the first model may be achieved by the following process:

The user activates the scaling mode, and then the mouse is moved onto the first model to be scaled and approaches any capture object. When the mouse approaches the center point or vertex of a plane on the bounding box of the model, the state without confirmation operation may be regarded as the hovering state. The scaling handle is highlighted in the hovering state. When the user clicks confirmation, the scaling handle continues to be displayed (the display style may be adjusted, such as non-highlighting). The user moves the mouse, and the capture element moves with the mouse. When the user confirms the movement position of the capture element, a scaling ratio is determined based on the movement position of the capture element, and the scaling of the first model is completed according to this scaling ratio and a scaling ratio corresponding to the type of the capture element. When the scaling is completed, the user may activate other functions/modes through the keyboard, mouse, etc. to terminate the scaling mode.

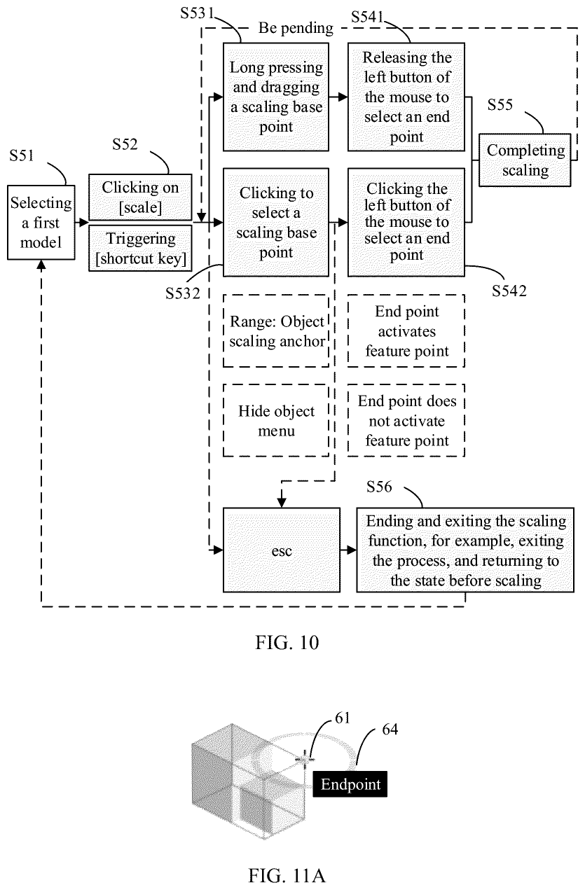

FIG. 10 is a schematic diagram of the operation manner in the scaling mode in an application example of an embodiment of the present disclosure. As shown in FIG. 10, the method for controlling model operation may include:
S51: selecting a first model; and
S52: activating the scaling mode, for example, by clicking on the tab “scale” or by triggering a shortcut key.

In one implementation, the method for controlling model operation further includes:
S531: long pressing and dragging a scaling base point (a capture element meeting the capture condition); and
S541: releasing the left button of the mouse to select an end point (to confirm the movement position of the capture element).

In another implementation, the method for controlling model operation further includes:
S532: clicking to select a scaling base point (a capture element meeting the capture condition); and
S542: clicking the left button of the mouse to select an end point (to confirm the movement position of the capture element).

Moreover, the method for controlling model operation further includes:
S55 after S541 or S542: completing the scaling; and
S56 in the execution process of S52 to S541 or S542: exiting the process, and returning the first model to the state before scaling.

In some embodiments, the processing information related to the capture element includes: an angle of rotation with the capture element as a rotation center point in the rotation mode. Correspondingly, the above-mentioned step S730 of determining the arrangement information of the first model based on the processing information related to the capture element and the relative position between the capture element and the first model includes: determining a rotation plane based on the type information of the capture element; and rotating the first model with a normal of the rotation plane as a rotation axis based on the relative position between the capture element and the first model and the angle, to obtain a rotation position of the first model.

That is, the movement of the cursor position is used to determine the angle of rotation with the capture element as the rotation center point in rotation mode. As in the above-mentioned embodiments, the movement of the cursor position may be used to determine the positions of other points, lines or surfaces with the capture element as the datum point. Optionally, the movement of the cursor position may be used to determine two edges connected to the capture element on the rotation plane, so as to determine the angle of rotation with the capture element as the rotation center point based on the two edges. Here, the rotation plane is determined based on the type information of the capture element. After the rotation plane and the angle of rotation are obtained, the first model may be rotated with the normal of the rotation plane as the rotation axis based on the relative position between the capture element and the first model and the angle, to obtain the rotation position (i.e., the position after rotation) of the first model.

In some embodiments, the step of determining the processing information related to the capture element based on the movement of the cursor position includes:
in response to detecting a first confirmation operation during movement of the cursor position, determining a rotation start edge; where the rotation start edge penetrates through the capture element and a detection point corresponding to the first confirmation operation;
in response to detecting a second confirmation operation during movement of the cursor position, determining a rotation end edge; where the rotation end edge penetrates through the capture element and a detection point corresponding to the second confirmation operation; and
determining the angle of rotation with the capture element as the rotation center point based on the rotation start edge and the rotation end edge.

Optionally, the rotation plane may be determined when it is confirmed that the capture element and the cursor position meet the capture condition. When the rotation plane is determined, the movement of the cursor position is used to determine the rotation start edge and the rotation end edge. Specifically, when the user moves the cursor position to a certain point and performs the confirmation operation (such as clicking), the connecting line between this point and the capture element is the rotation start edge; then the user may move the cursor position to another point and perform the confirmation operation, and thus the connecting line between this point and the capture element is the rotation end edge; and the angle of rotation with the capture element as the center point may be determined based on the two edges. According to the above method, the angle of rotation can be determined through the visual user interaction, thereby facilitating the accurate rotation.

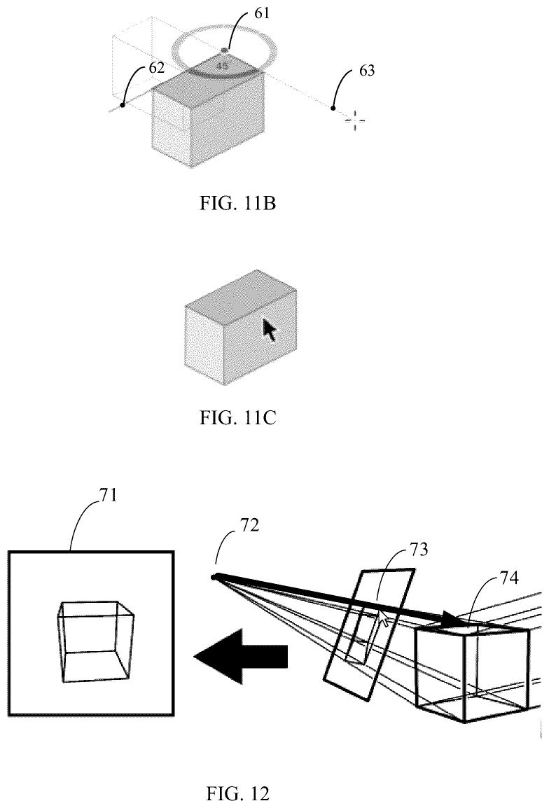

FIGS. 11A to 11C are schematic diagrams of the operation manner in the rotation mode. As shown in FIG. 11A, in the rotation mode, when the cursor position is close to any capture element (such as an endpoint 61) of the first model, a rotation plane identifier 64 (such as a circle) and the type information “endpoint” of the capture element will be displayed. At this time, if the user inputs a confirmation operation, such as clicking the mouse, the capture element and the rotation plane are confirmed. Then the user moves the mouse to move the cursor position. When the cursor position moves to a point 62 as shown in FIG. 11B, the user clicks confirmation to use the connecting line between the point 62 and the endpoint 61 as the rotation start edge. Then the user continues to move the mouse to move the cursor position. When the cursor position moves to a point 63 as shown in FIG. 11B, the user clicks confirmation again to use the connecting line between the point 63 and the endpoint 61 as the rotation end edge. At this time, the angle of 45° formed by the two edges is the angle of rotation. Based on this angle, the first model is rotated with the endpoint 61 as the rotation center point and the normal of the rotation plane penetrating through the rotation center point as the rotation axis. The rotated first model can be seen in FIG. 11B. Then the user may exit the rotation mode through the mode switching operation, and at this time, the interactive interface is displayed as shown in FIG. 11C. In this example, in order to assist the user operation and improve the user experience, when the rotation start and end edges are selected, the connecting line between the cursor position and the rotation center point is always displayed; when the rotation end edge is selected, the angle value can be always displayed according to the movement position of the capture element, to facilitate the user to confirm the rotation end edge.

In some embodiments, the rotation plane may be a pre-configured plane corresponding to the type information of the capture element. For example, when the type information of the capture element is a vertex of the bounding box, the rotation plane may be one of three planes containing the vertex in the bounding box. When the type information of the capture element is a center point of a plane on the bounding box, the rotation plane may be the plane on the bounding box. When the type information of the capture element is an edge on the bounding box, the rotation plane may be one of two planes containing the edge on the bounding box.

In some embodiments, the method for controlling model operation further includes:
in the rotation mode, in response to detecting in the model arrangement space that an adsorption condition is met between the cursor position and any capture element of the first model and the type information of the capture element is a vertex of a bounding box of the first model, displaying a rotation plane identifier on a plane intersecting with the cursor position on the bounding box, and detecting a confirmation operation for the type information; where the confirmation operation for the type information is further used to confirm the plane intersecting with the cursor position as the rotation plane.

Specifically, in the above-mentioned step S710, in rotation mode, if the cursor position and any capture element meet the adsorption condition and the type information of the capture element is a center point of a plane on the bounding box, the type information “center point” is displayed (optionally, a rotation plane identifier may also be displayed on this plane). When the user confirms the type information, the electronic device simultaneously determines that this plane is the rotation plane. If the cursor position and any capture element meet the adsorption condition and the type information of the capture element is a vertex of the bounding box, the electronic device will select a plane intersecting with the cursor position from three planes where the vertex is located as the rotation plane according to the cursor position, and display a rotation plane identifier to the user. At this time, if the user inputs a confirmation operation for the type information, this plane is also confirmed as the rotation plane. If the user moves the cursor position so that the cursor position and this vertex still meet the capture condition but the plane intersecting with the cursor position changes, the electronic device will update the rotation plane and display a new rotation plane identifier. In this way, the rotation plane identifier can assist the user in selecting the rotation plane from the three planes where the vertex is located.

To facilitate understanding of the plane intersecting with the cursor position on the bounding box, an explanation is provided below in combination with FIG. 12. As shown in FIG. 12, the picture presented on the interactive interface 71 is a picture taken from the current viewing angle 72 of the camera (the viewing angle of the virtual camera) toward the first model, that is, the interactive interface 71 presents an image of a projection plane 73 on the path projected from the current viewing angle 72 of the camera to the model. The cursor controlled by the user moves on the projection plane 73. The plane 74 intersecting with the cursor position in the embodiment of the present disclosure refers to a plane intersecting with a projection ray where the cursor position is located, and the projection ray is a ray pointing from the current viewing angle of the camera to the cursor position. In the example shown in FIG. 12, the plane is the upper surface of the bounding box.

When the type of the capture element is an edge on the bounding box, the rotation plane may be determined from two planes where the edge on the bounding box is located in a manner similar to that in the above embodiments.

In some embodiments, when the type information of the capture element is not a pre-set specific type, the rotation plane is a default plane; and the specific type includes a vertex of a bounding box, a center point of each plane on the bounding box, and an edge of the bounding box.

Exemplarily, the default plane may be the XY plane, XZ plane or YZ plane in the model arrangement space.

For example, when the type information of the capture element is a point on an object, that is, a point on a surface (such as a grid surface, a mesh surface) of the first model, the rotation plane is the default plane.

In actual applications, when the type information of the capture element is not a specific type, the plane where the capture element is located will vary a lot. If the rotation plane identifier is displayed according to the cursor position, the background response speed will be affected. In addition, the diversity and complexity of the inclination angle of the plane will also make it impossible for the user to select the precise rotation plane. In the above-mentioned embodiments, the manners to determine the rotation plane from the capture element are restricted to a few capture element types, the user can be provided with the freedom to select the rotation plane, and the default plane is used as the rotation plane for other types, avoiding the impact on the response speed and the incorrect selection of the rotation plane, and thereby improving the effect of precise rotation.

In some embodiments, the step of determining the processing information related to the capture element based on the movement of the cursor position includes: when the cursor position moves to meet the adsorption condition with respect to a reference element in the model arrangement space, determining the processing information related to the capture element based on a position of the reference element.

Taking the processing information related to the capture element being the movement position of the capture element as an example, the movement position of the capture element is determined based on the movement of the cursor position. Specifically, if the cursor position moves to a blank position in the model arrangement space, the movement position of the capture element is the cursor position; if the cursor position moves to a position that meets the adsorption condition with respect to certain reference elements in the model arrangement space, the movement position of the capture element is a position related to these reference elements. For example, the reference element may include a reference point, such as a vertex of another model; and the movement position of the capture element may be the position of the reference point (that is, the capture element is adsorbed to the position of the reference point). For another example, the reference element may include a reference line, such as a reference line drawn by the user in the model arrangement space, or an edge of another model; and the movement position of the capture element may be the position of the projection point of the cursor position on the reference line, or the position of the point on the reference line closest to the cursor position.

Exemplarily, the adsorption condition is related to the distance between the cursor position and the reference element. For example, the adsorption condition is that this distance is less than a second value. The second value may be a preset threshold or a value determined based on the size information related to the reference element.

According to the above embodiments, the processing information related to the captured element is determined by adsorbing the reference element in the model arrangement space, which can help the user accurately provide the processing information related to the captured element through interactive operations, thereby facilitating the accurate arrangement.

Exemplarily, the reference element includes a straight line along the axial direction of the model arrangement space, such as a straight line along the X-axis, Y-axis or Z-axis direction of the model arrangement space.

The method for controlling model operation in the embodiments of the present disclosure can solve the problem of difficulty in accurate capture when there are many capture elements, thereby supporting the setting of multiple types and a large number of capture elements to achieve accurate capture and adsorption, and facilitating the accurate arrangement of the model.

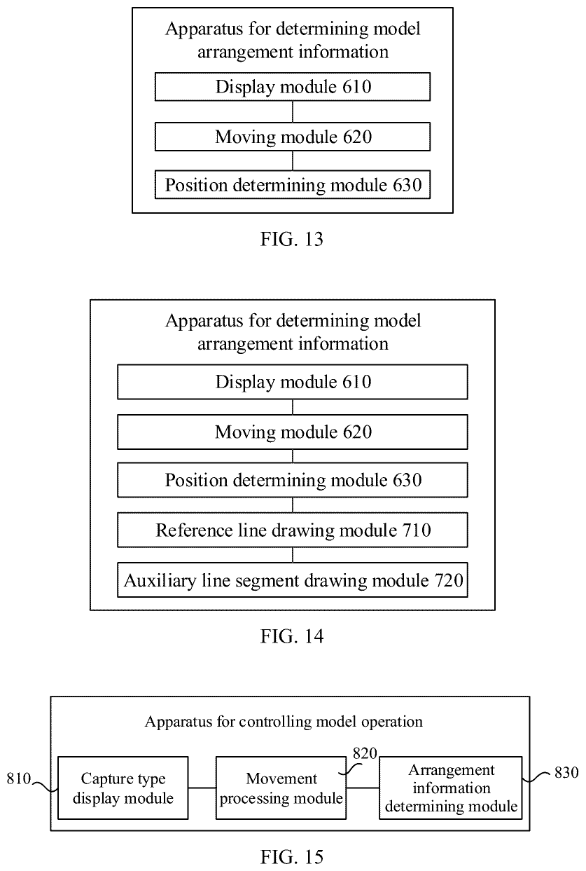

According to an embodiment of the present disclosure, the present disclosure further provides an apparatus for determining model arrangement information. FIG. 13 shows a schematic block diagram of the apparatus for determining model arrangement information according to the embodiment of the present disclosure. As shown in FIG. 13, the apparatus for determining model arrangement information includes:
a display module 610 configured to, in response to triggering to arrange a first model on a house layout design drawing, display at least one capture element of the first model; where the house layout design drawing includes a first reference line drawn according to a user operation instruction;
a moving module 620 configured to, in response to detecting a drag operation on a first capture element among the at least one capture element, move the first capture element and the first model according to a trajectory corresponding to the drag operation and a relative position between the first capture element and the first model; and
a position determining module 630 configured to, if a preset adsorption condition is met between the first reference line and the first capture element and an arrangement confirmation instruction input by a user is detected during movement, determine an arrangement position of the first capture element based on a position of the first reference line, and determine an arrangement position of the first model based on the relative position between the first capture element and the first model.

In some embodiments, as shown in FIG. 14, the apparatus for determining model arrangement information further includes a reference line drawing module 710 configured to:
in a reference line drawing mode, in response to detecting a datum point confirmation instruction on the house layout design drawing, determine reference line datum information based on a detection position of the datum point confirmation instruction, and start to detect a drawing confirmation instruction on the house layout design drawing; and
generate the first reference line on the house layout design drawing based on the reference line datum information and position information indicated by the drawing confirmation instruction.

In some embodiments, when a datum point indicated by the datum point confirmation instruction is located on a linear element in the house layout design drawing, the reference line datum information is the linear element; and
the reference line drawing module 710 is further configured to:
generate the first reference line parallel to the linear element on the house layout design drawing according to a distance value included in the drawing confirmation instruction and/or a detection position of the drawing confirmation instruction.

In some embodiments, the linear element in the house layout design drawing includes at least one of: a second reference line drawn according to a user operation instruction, a line segment of a house layout component, or an external frame line of a second model arranged on the house layout design drawing.

In some embodiments, when a datum point indicated by the datum point confirmation instruction is not located on a linear element in the house layout design drawing, the reference line datum information is the datum point; and the first reference line penetrates through the datum point and the position information indicated by the drawing confirmation instruction.

In some embodiments, the at least one capture element includes at least one of: an element on an external frame of the first model, a point on a mesh surface of the first model, a key point determined when the first model is modeled, an auxiliary line segment of the first model, or a key point on the auxiliary line segment.

In some embodiments, as shown in FIG. 14, the apparatus for determining model arrangement information further includes an auxiliary line segment drawing module 720 configured to:
in an auxiliary line drawing mode, detect a start point confirmation instruction and an end point confirmation instruction detected on the house layout design drawing;
generate the auxiliary line segment based on a start point indicated by the start point confirmation instruction and an end point indicated by the end point confirmation instruction; and
bind the auxiliary line segment with the first model on the house layout design drawing.

In some embodiments, the start point confirmation instruction includes a click instruction for the start point, or a confirmation instruction for adsorbing a point on the house layout design drawing as the start point; and
the end point confirmation instruction includes a click instruction for the end point, or a confirmation instruction for adsorbing a point on the house layout design drawing as the end point.

In some embodiments, the display module 610 is specifically configured to:
in response to triggering to arrange a first model on a house layout design drawing, determine a type of a capture element to be displayed according to size information of an external frame of the first model; and
display at least one capture element of the first model according to the type of the capture element to be displayed.

In some embodiments, when the area of the external frame of the first model is greater than a preset first threshold, the at least one capture element displayed includes at least one of: an element on the external frame of the first model, a point on a mesh surface of the first model, a key point determined when the first model is modeled, or an auxiliary line of the first model.

In some embodiments, when the area of the external frame of the first model is less than the preset first threshold and greater than a preset second threshold, the at least one capture element displayed includes at least one of: an element on the external frame of the first model, and an auxiliary line of the first model.

In some embodiments, when the area of the external frame of the first model is less than the preset second threshold, the at least one capture element displayed includes at least one element on the external frame of the first model.

In some embodiments, in an arrangement off mode, the at least one capture element includes a linear element on the external frame of the first model.

In some embodiments, in an arrangement on mode, the at least one capture element includes at least one of: a point and/or a line segment on the external frame of the first model, a point on a mesh surface of the first model, a key point determined when the first model is modeled, or a point and/or a line segment on an auxiliary line of the first model.

According to an embodiment of the present disclosure, the present disclosure further provides an apparatus for controlling model operation. FIG. 15 shows a schematic block diagram of the apparatus for controlling model operation according to the embodiment of the present disclosure. As shown in FIG. 15, the apparatus for controlling model operation includes:
a capture type display module 810 configured to, in response to detecting that a capture condition is met between a cursor position in a model arrangement space and any capture element of the first model, display type information of the capture element;
a movement processing module 820 configured to, in response to detecting a confirmation operation for the type information, determine processing information related to the capture element based on movement of the cursor position; and
an arrangement information determining module 830 configured to determine arrangement information of the first model based on the processing information related to the capture element and a relative position between the capture element and the first model.

In some embodiments, the processing information related to the capture element includes: a movement position of the capture element in a movement mode; and the arrangement information determining module 830 is specifically configured to: determine a movement position of the first model based on the movement position of the capture element and the relative position between the capture element and the first model.

In some embodiments, the processing information related to the capture element includes: a movement position of the capture element in a copy mode; and the arrangement information determining module 830 is specifically configured to: in response to detecting a confirmation operation for the movement position of the capture element, determine the movement position of the capture element as a copy end point; and determine a copy position of the first model based on the copy end point and the relative position between the capture element and the first model.

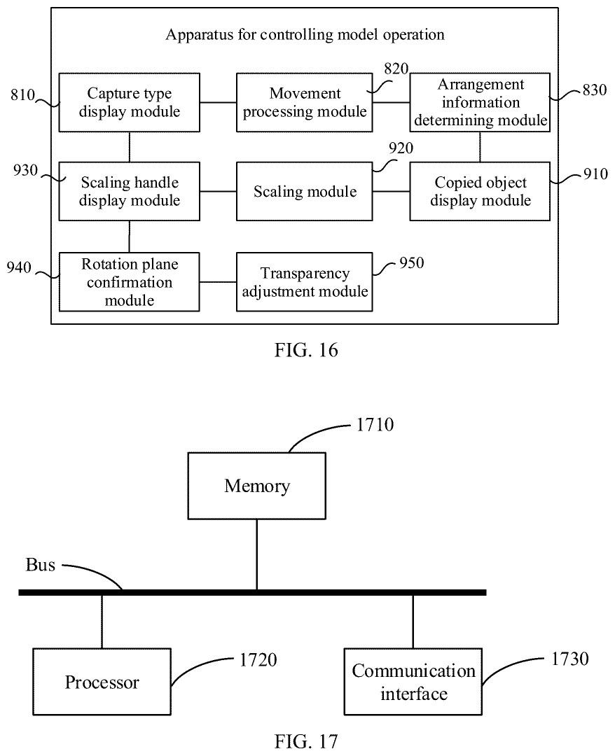

As shown in FIG. 16, the apparatus for controlling model operation further includes:
a copied object display module 910 configured to display a copied object of the first model at the copy position.

In some embodiments, the processing information related to the capture element includes: a movement position of the capture element in a scaling mode; and the arrangement information determining module 830 is specifically configured to: determine a scaling parameter of the first model based on the movement position of the capture element and the relative position between the capture element and the first model.

In some embodiments, as shown in FIG. 16, the apparatus for controlling model operation further includes:
a scaling module 920 configured to display the scaled first model based on a scaling type corresponding to the type information of the capture element and the scaling parameter.

In some embodiments, as shown in FIG. 16, the apparatus for controlling model operation further includes:
a scaling handle display module 930 configured to, in the scaling mode, in response to detecting in the model arrangement space that the capture condition is met between the cursor position and any capture element of the first model, display a scaling handle based on the type information of the capture element; where the scaling handle is used to prompt the scaling type corresponding to the type information of the capture element.

In some embodiments, the processing information related to the capture element includes: an angle of rotation with the capture element as a rotation center point in a rotation mode; and the arrangement information determining module 830 is specifically configured to:
determine a rotation plane based on the type information of the capture element; and
rotate the first model with a normal of the rotation plane as a rotation axis based on the relative position between the capture element and the first model and the angle, to obtain a rotation position of the first model.

In some embodiments, the movement processing module 820 is specifically configured to:
in response to detecting a first confirmation operation during movement of the cursor position, determine a rotation start edge; where the rotation start edge penetrates through the capture element and a detection point corresponding to the first confirmation operation;
in response to detecting a second confirmation operation during movement of the cursor position, determine a rotation end edge; where the rotation end edge penetrates through the capture element and a detection point corresponding to the second confirmation operation; and
determine the angle of rotation with the capture element as the rotation center point based on the rotation start edge and the rotation end edge.

In some embodiments, as shown in FIG. 16, the apparatus for controlling model operation further includes:
a rotation plane confirmation module 940 configured to, in the rotation mode, in response to detecting in the model arrangement space that an adsorption condition is met between the cursor position and any capture element of the first model and the type information of the capture element is a vertex of a bounding box of the first model, display a rotation plane identifier on a plane intersecting with the cursor position on the bounding box, and detect a confirmation operation for the type information; where the confirmation operation for the type information is further used to confirm the plane intersecting with the cursor position as the rotation plane.

In some embodiments, when the type information of the capture element is not a pre-set specific type, the rotation plane is a default plane; and the specific type includes a vertex of a bounding box, a center point of each plane on the bounding box, and an edge of the bounding box.

In some embodiments, the movement processing module 820 is specifically configured to:
when the cursor position moves to meet the adsorption condition with respect to a reference element in the model arrangement space, determine the processing information related to the capture element based on a position of the reference element.

In some embodiments, the reference element includes a straight line along an axial direction of the model arrangement space.

In some embodiments, as shown in FIG. 16, the apparatus for controlling model operation further includes:
a transparency adjustment module 950 configured to, when the cursor position and a capture element invisible from a current viewing angle of a camera meet the capture condition, reduce display transparency of the first model to display the capture element.

For the description of specific functions and examples of the modules and sub-modules of the apparatus of the embodiment of the present disclosure, reference may be made to the relevant description of the corresponding steps in the above-mentioned method embodiments, and details are not repeated here.

In the technical solution of the present disclosure, the acquisition, storage and application of the user's personal information involved are in compliance with relevant laws and regulations, and do not violate public order and good customs.

FIG. 17 is a structural block diagram of an electronic device according to an embodiment of the present disclosure. As shown in FIG. 17, the electronic device includes: a memory 1710 and a processor 1720, and the memory 1710 stores a computer program that can run on the processor 1720. There may be one or more memories 1710 and processors 1720. The memory 1710 may store one or more computer programs, and the one or more computer programs cause the electronic device to perform the method provided in the above method embodiment, when executed by the electronic device. The electronic device may also include: a communication interface 1730 configured to communicate with an external device for data interactive transmission.

If the memory 1710, the processor 1720 and the communication interface 1730 are implemented independently, the memory 1710, the processor 1720 and the communication interface 1730 may be connected to each other and complete communication with each other through a bus. The bus may be an Industry Standard Architecture (ISA) bus, a Peripheral Component Interconnect (PCI) bus, or an Extended Industry Standard Architecture (EISA) bus, etc. The bus may be divided into address bus, data bus, control bus, etc. For ease of representation, the bus is represented by only one thick line in FIG. 17, but it does not mean that there is only one bus or one type of bus.

Optionally, in a specific implementation, if the memory 1710, the processor 1720 and the communication interface 1730 are integrated on one chip, the memory 1710, the processor 1720 and the communication interface 1730 may communicate with each other through an internal interface.

It should be understood that the above-mentioned processor may be a Central Processing Unit (CPU) or other general-purpose processor, a Digital Signal Processor (DSP), an Application Specific Integrated Circuit (ASIC), a Field Programmable Gate Array (FPGA) or other programmable logic device, a discrete gate or transistor logic device, a discrete hardware component, etc. The general-purpose processor may be a microprocessor or any conventional processor, etc. It is worth noting that the processor may be a processor that supports the Advanced RISC Machines (ARM) architecture.

Further, optionally, the above-mentioned memory may include a read-only memory and a random access memory, and may also include a non-volatile random access memory. The memory may be a volatile memory or a non-volatile memory, or may include both a volatile memory and a non-volatile memory. The non-volatile memory may include a Read-Only Memory (ROM), a Programmable ROM (PROM), an Erasable PROM (EPROM), an Electrically EPROM

(EEPROM) or a flash memory. The volatile memory may include a Random Access Memory (RAM), which acts as an external cache. By way of illustration and not limitation, many forms of RAMs are available, for example, Static RAM (SRAM), Dynamic Random Access Memory (DRAM), Synchronous DRAM (SDRAM), Double Data Date SDRAM (DDR SDRAM), Enhanced SDRAM (ESDRAM), Synchlink DRAM (SLDRAM) and Direct RAMBUS RAM (DR RAM).

The above embodiments may be implemented in whole or in part by software, hardware, firmware or any combination thereof. When implemented by software, they may be implemented in the form of a computer program product in whole or in part. The computer program product includes one or more computer instructions. When the computer instructions are loaded and executed on a computer, the processes or functions described in the embodiments of the present disclosure are generated in whole or in part. The computer may be a general-purpose computer, a special-purpose computer, a computer network, or other programmable device. The computer instructions may be stored in a computer readable storage medium or transmitted from a computer readable storage medium to another computer readable storage medium. For example, the computer instructions may be transmitted from a website, computer, server or data center to another website, computer, server or data center in a wired (e.g., coaxial cable, optical fiber, Digital Subscriber Line (DSL)) or wireless (e.g., infrared, Bluetooth, microwave, etc.) way. The computer readable storage medium may be any available medium that can be accessed by a computer, or a data storage device such as server or data center that is integrated with one or more available media. The available media may be magnetic media (for example, floppy disk, hard disk, magnetic tape), optical media (for example, Digital Versatile Disc (DVD)), or semiconductor media (for example, Solid State Disk (SSD)), etc. It is worth noting that the computer readable storage medium mentioned in the present disclosure may be a non-volatile storage medium, in other words, may be a non-transitory storage medium.

Those having ordinary skill in the art can understand that all or some of the steps for implementing the above embodiments may be completed by hardware, or may be completed by instructing related hardware through a program. The program may be stored in a computer readable storage medium. The above-mentioned storage medium may be a read-only memory, a magnetic disk or an optical disk, etc.

In the description of the embodiments of the present disclosure, the description with reference to the terms “one embodiment”, “some embodiments”, “example”, “specific example” or “some examples”, etc. means that specific features, structures, materials or characteristics described in conjunction with the embodiment or example are included in at least one embodiment or example of the present disclosure. Moreover, the specific features, structures, materials or characteristics described may be combined in a suitable manner in any one or more embodiments or examples. In addition, those skilled in the art can integrate and combine different embodiments or examples and features of different embodiments or examples described in this specification without conflicting with each other.

In the description of the embodiments of the present disclosure, “/” represents or, unless otherwise specified. For example, A/B may represent A or B. The term “and/or” herein only describes an association relation of associated objects, which indicates that there may be three kinds of relations, for example, A and/or B may indicate that only A exists, or both A and B exist, or only B exists.

In the description of the embodiments of the present disclosure, the terms “first” and “second” are only for purpose of description, and cannot be construed to indicate or imply the relative importance or implicitly point out the number of technical features indicated. Therefore, the feature defined with “first” or “second” may explicitly or implicitly include one or more features. In the description of the embodiments of the present disclosure, “multiple” means two or more, unless otherwise specified.

The above descriptions are only exemplary embodiments of the present disclosure and not intended to limit the present disclosure. Any modifications, equivalent replacements, improvements and others made within the spirit and principle of the present disclosure shall be contained in the protection scope of the present disclosure.

What is claimed is:

1. A method for determining model arrangement information, comprising:
in response to triggering to arrange a first model on a house layout design drawing, displaying at least one capture element of the first model; wherein the house layout design drawing comprises a first reference line drawn according to a user operation instruction;
in response to detecting a drag operation on a first capture element among the at least one capture element, moving the first capture element and the first model according to a trajectory corresponding to the drag operation and a relative position between the first capture element and the first model; and
in a case of a preset adsorption condition is met between the first reference line and the first capture element and an arrangement confirmation instruction input by a user is detected during movement, determining an arrangement position of the first capture element based on a position of the first reference line, and determining an arrangement position of the first model based on the relative position between the first capture element and the first model.

2. The method of claim 1, further comprising:
in a reference line drawing mode, in response to detecting a datum point confirmation instruction on the house layout design drawing, determining reference line datum information based on a detection position of the datum point confirmation instruction, and starting to detect a drawing confirmation instruction on the house layout design drawing; and
generating the first reference line on the house layout design drawing based on the reference line datum information and position information indicated by the drawing confirmation instruction.

3. The method of claim 2, wherein in a case of a datum point indicated by the datum point confirmation instruction is located on a linear element in the house layout design drawing, the reference line datum information is the linear element; and
generating the first reference line on the house layout design drawing based on the reference line datum information and the position information indicated by the drawing confirmation instruction, comprises:
generating the first reference line parallel to the linear element on the house layout design drawing according to a distance value comprised in the drawing confirmation instruction and/or a detection position of the drawing confirmation instruction.

4. The method of claim 3, wherein the linear element in the house layout design drawing comprises at least one of: a second reference line drawn according to a user operation instruction, a line segment of a house layout component, or an external frame line of a second model arranged on the house layout design drawing.

5. The method of claim 2, wherein in a case of a datum point indicated by the datum point confirmation instruction is not located on a linear element in the house layout design drawing, the reference line datum information is the datum point; and the first reference line penetrates through the datum point and the position information indicated by the drawing confirmation instruction.

6. The method of claim 1, wherein the at least one capture element comprises at least one of:
an element on an external frame of the first model, a point on a mesh surface of the first model, a key point determined when the first model is modeled, an auxiliary line segment of the first model, or a key point on the auxiliary line segment.

7. The method of claim 6, further comprising:
in an auxiliary line drawing mode, detecting a start point confirmation instruction and an end point confirmation instruction detected on the house layout design drawing;
generating the auxiliary line segment based on a start point indicated by the start point confirmation instruction and an end point indicated by the end point confirmation instruction; and
binding the auxiliary line segment with the first model.

8. The method of claim 7, wherein the start point confirmation instruction comprises a click instruction for the start point, or a confirmation instruction for adsorbing a point on the house layout design drawing as the start point; and
the end point confirmation instruction comprises a click instruction for the end point, or a confirmation instruction for adsorbing a point on the house layout design drawing as the end point.

9. The method of claim 6, wherein the in response to triggering to arrange a first model on a house layout design drawing, displaying at least one capture element of the first model, comprises:
in response to triggering to arrange a first model on a house layout design drawing, determining a type of a capture element to be displayed according to size information of an external frame of the first model; and
displaying at least one capture element of the first model according to the type of the capture element to be displayed.

10. The method of claim 9, wherein in a case of the size information of the external frame of the first model is greater than a preset first threshold, the type of the capture element to be displayed comprises at least one of: an element on the external frame of the first model, a point on a mesh surface of the first model, a key point determined when the first model is modeled, an auxiliary line segment of the first model, or a key point on the auxiliary line segment.

11. The method of claim 10, wherein in a case of the size information of the external frame of the first model is less than the preset first threshold, the type of the capture element to be displayed comprises at least one of: an element on the external frame of the first model, and an auxiliary line segment of the first model.

12. The method of claim 1, wherein, in an arrangement off mode, the at least one capture element comprises an element on an external frame of the first model.

13. The method of claim 1, wherein, in an arrangement on mode, the at least one capture element comprises at least one of: an element on an external frame of the first model, a point on a mesh surface of the first model, a key point determined when the first model is modeled, an auxiliary line segment of the first model, or a key point on the auxiliary line segment.

14. An electronic device, comprising:
at least one processor; and
a memory connected in communication with the at least one processor;
wherein the memory stores an instruction executable by the at least one processor, and the instruction is executed by the at least one processor to enable the at least one processor to:
in response to triggering to arrange a first model on a house layout design drawing, display at least one capture element of the first model; wherein the house layout design drawing comprises a first reference line drawn according to a user operation instruction;
in response to detecting a drag operation on a first capture element among the at least one capture element, move the first capture element and the first model according to a trajectory corresponding to the drag operation and a relative position between the first capture element and the first model; and
in a case of a preset adsorption condition is met between the first reference line and the first capture element and an arrangement confirmation instruction input by a user is detected during movement, determine an arrangement position of the first capture element based on a position of the first reference line, and determine an arrangement position of the first model based on the relative position between the first capture element and the first model.

15. The electronic device of claim 14, wherein the instruction is executed by the at least one processor to further enable the at least one processor to:
in a reference line drawing mode, in response to detecting a datum point confirmation instruction on the house layout design drawing, determine reference line datum information based on a detection position of the datum point confirmation instruction, and start to detect a drawing confirmation instruction on the house layout design drawing; and
generate the first reference line on the house layout design drawing based on the reference line datum information and position information indicated by the drawing confirmation instruction.

16. The electronic device of claim 14, wherein the at least one capture element comprises at least one of: an element on an external frame of the first model, a point on a mesh surface of the first model, a key point determined when the first model is modeled, an auxiliary line segment of the first model, or a key point on the auxiliary line segment.

17. The electronic device of claim 16, wherein the instruction is executed by the at least one processor to further enable the at least one processor to:
in an auxiliary line drawing mode, detect a start point confirmation instruction and an end point confirmation instruction detected on the house layout design drawing;
generate the auxiliary line segment based on a start point indicated by the start point confirmation instruction and an end point indicated by the end point confirmation instruction; and
bind the auxiliary line segment with the first model.

18. A non-transitory computer-readable storage medium storing a computer instruction thereon, wherein the computer instruction is configured to cause a computer to:
in response to triggering to arrange a first model on a house layout design drawing, display at least one capture element of the first model; wherein the house layout design drawing comprises a first reference line drawn according to a user operation instruction;
in response to detecting a drag operation on a first capture element among the at least one capture element, move the first capture element and the first model according to a trajectory corresponding to the drag operation and a relative position between the first capture element and the first model; and
in a case of a preset adsorption condition is met between the first reference line and the first capture element and an arrangement confirmation instruction input by a user is detected during movement, determine an arrangement position of the first capture element based on a position of the first reference line, and determine an arrangement position of the first model based on the relative position between the first capture element and the first model.

19. The non-transitory computer-readable storage medium of claim 18, wherein the computer instruction is further configured to cause the computer to:
in a reference line drawing mode, in response to detecting a datum point confirmation instruction on the house layout design drawing, determine reference line datum information based on a detection position of the datum point confirmation instruction, and start to detect a drawing confirmation instruction on the house layout design drawing; and
generate the first reference line on the house layout design drawing based on the reference line datum information and position information indicated by the drawing confirmation instruction.

20. The non-transitory computer-readable storage medium of claim 18, wherein the at least one capture element comprises at least one of: an element on an external frame of the first model, a point on a mesh surface of the first model, a key point determined when the first model is modeled, an auxiliary line segment of the first model, or a key point on the auxiliary line segment.
